(19) United States
(12) Patent Application Publication
(10) Pub. No.: US 2025/0246570 A1
(43) Pub. Date: Jul. 31, 2025

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventor: Taehyung KIM, Suwon-si (KR)

(73) Assignee: SAMSUNG ELECTRONICS CO., LTD., Suwon-si (KR)

(21) Appl. No.: 18/952,483

(22) Filed: Nov. 19, 2024

(30) Foreign Application Priority Data
Jan. 26, 2024 (KR) 10-2024-0012022

(51) Int. Cl. H01L 23/00; H01L 23/29; H01L 25/065

(52) U.S. Cl. CPC H01L 24/20; H01L 23/293; H01L 24/19; H01L 24/24; H01L 25/0657; H01L 2224/19; H01L 2224/2101; H01L 2224/214; H01L 2224/215; H01L 2224/24051; H01L 2224/24146; H01L 2224/24226; H01L 2225/06524; H01L 2225/06562

(57) ABSTRACT

A semiconductor package may include a package substrate including a substrate pad; at least one semiconductor chip including a chip pad; and a powder layer stacked structure covering the semiconductor chip, the powder layer stacked structure including powder layers stacked in a vertical direction. Each of the powder layers may include a metal powder layer and a molding layer arranged in a horizontal direction. The metal powder layers of the powder layer stacked structure may be connected to each other to form a bonding powder structure, and the bonding powder structure may electrically connect the substrate pad and the chip pad.

### CROSS-REFERENCE TO RELATED APPLICATION

This application claims priority under 35 USC § 119 to Korean Patent Application No. 10-2024-0012022, filed on Jan. 26, 2024, in the Korean Intellectual Property Office (KIPO), the disclosure of which is incorporated by reference herein in its entirety.

### BACKGROUND

### 1. Field

One or more example embodiments relate to a semiconductor package and a method of manufacturing the semiconductor package. Particularly, one or more example embodiments relate to a semiconductor package including an electrical connection member and a method of manufacturing the same.

### 2. Description of the Related Art

A semiconductor package may include at least one semiconductor chip, and the semiconductor chip may be electrically connected to a package substrate using a bonding wire. A bonding pad on a surface of the semiconductor chip and the bonding wire may be bonded to each other using a bonding ball on the bonding pad. The bonding ball may have a diameter greater than a diameter of the bonding wire, and thus the bonding pad of the semiconductor chip may have a width greater than the diameter of the bonding ball. When the diameter of the bonding wire is decreased, a defect of the bonding may occur. Therefore, a downsizing of the bonding pad of the semiconductor chip may be difficult.

### SUMMARY

One or more example embodiments provide a semiconductor package including a bonding wire and a method for manufacturing the same.

According to an aspect of one or more example embodiments, a semiconductor package includes: a package substrate including a substrate pad; at least one semiconductor chip including a chip pad, wherein the at least one semiconductor chip being provided on the package substrate; and a powder layer stacked structure covering the semiconductor chip, wherein the powder layer stacked structure is provided on the package substrate, wherein the powder layer stacked structure includes powder layers stacked in a vertical direction, wherein each of the powder layers includes a metal powder layer and a molding layer arranged in a horizontal direction, wherein the metal powder layers of the powder layer stacked structure are connected to each other to form a bonding powder structure, and wherein the bonding powder structure electrically connects the substrate pad and the chip pad.

According to a further aspect of one or more example embodiments, a semiconductor package includes: a package substrate including a substrate pad; a first semiconductor chip including a first chip pad, wherein the first semiconductor chip is provided on the package substrate; a second semiconductor chip including a second chip pad, wherein the second semiconductor chip is provided on the first semiconductor chip, and wherein the second semiconductor chip exposes the first chip pads; and a powder layer stacked structure covering the first semiconductor chip and the second semiconductor chip, wherein the powder layer stacked structure is provided on the package substrate, wherein the powder layer stacked structure includes powder layers stacked in a vertical direction, wherein each of the powder layers includes a metal powder layer and a molding layer arranged in a horizontal direction, wherein the metal powder layers of the powder layer stacked structure are connected to each other to form a bonding powder structure, and wherein the bonding powder structure electrically connects the substrate pad and at least one of the first chip pad and the second chip pad.

According to a still further aspect of one or more example embodiments, a method for manufacturing a semiconductor package includes: stacking, on a package substrate, at least one semiconductor chip including a chip pad, wherein the package substrate includes a substrate pad; forming a first powder layer on the package substrate, the first powder layer including: a metal powder layer contacting the substrate pad; and a molding layer on the package substrate, the molding layer extending from sides of the metal powder layer; and repeatedly forming a plurality of powder layers, each including the metal powder layer and the molding layer, on the first powder layer to form a bonding wire powder structure including the metal powder layers and a molding structure including the molding layers, wherein the bonding wire powder structure is formed on the package substrate and the semiconductor chip, and wherein the bonding wire powder structure electrically connects the substrate pad and the chip pad.

However, the effects of one or more example embodiments are not limited to the effects mentioned above, and may be expanded in various ways without departing from the spirit and scope of one or more example embodiments.

### BRIEF DESCRIPTION OF THE DRAWINGS

The above and other aspects and features will be more apparent from the following description of one or more example embodiments taken in conjunction with the accompanying drawings, in which:

FIG. 1 is a cross-sectional view illustrating a semiconductor package according to one or more example embodiments;

FIG. 2 is a plan view illustrating a semiconductor package according to one or more example embodiments;

FIG. 3 is a cross-sectional view illustrating a semiconductor package according to one or more example embodiments;

FIG. 4 is a cross-sectional view illustrating a semiconductor package according to one or more example embodiments;

FIG. 5 is a cross-sectional view illustrating a semiconductor package according to one or more example embodiments;

FIG. 6 is a cross-sectional view illustrating a semiconductor package according to one or more example embodiments;

FIGS. 7, 8, 9, 10, 11, 12, 13, 14, 15, 16, 17, 18, 19 and 20 are cross-sectional views illustrating a method for manufacturing a semiconductor package according to one or more example embodiments;

FIG. 21 is a cross-sectional view illustrating a semiconductor package according to one or more example embodiments;

FIGS. 22 and 23 are cross-sectional views illustrating a method for manufacturing a semiconductor package according to one or more example embodiments;

FIG. 24 is a cross-sectional view illustrating a semiconductor package according to one or more example embodiments; and

FIGS. 25 and 26 are cross-sectional views illustrating a method of manufacturing a semiconductor package according to one or more example embodiments.

### DETAILED DESCRIPTION

Hereinafter, one or more example embodiments will be described in detail with reference to the accompanying drawings. The same reference numerals are used for the same components in the drawings, and duplicate descriptions thereof are omitted.

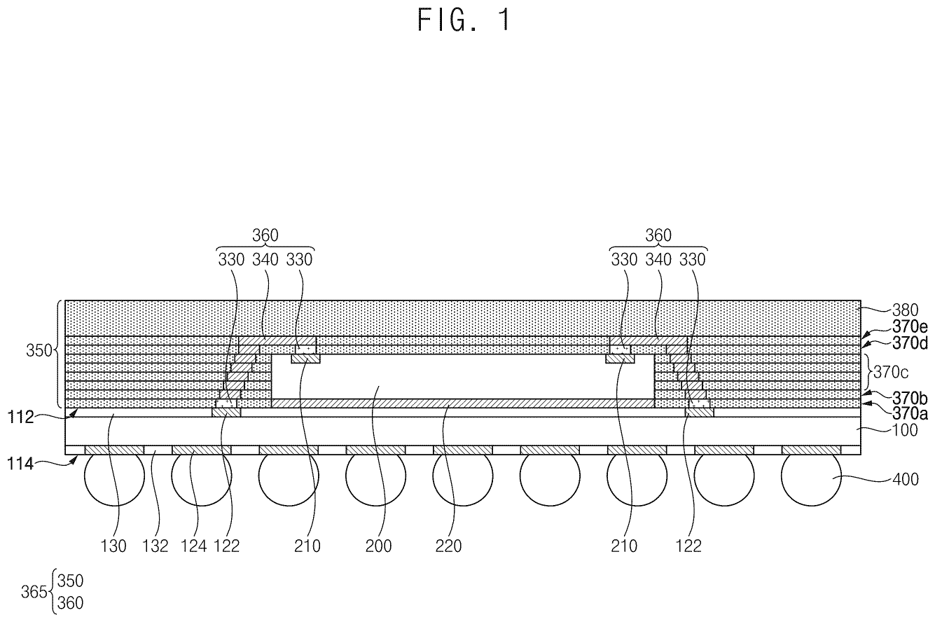

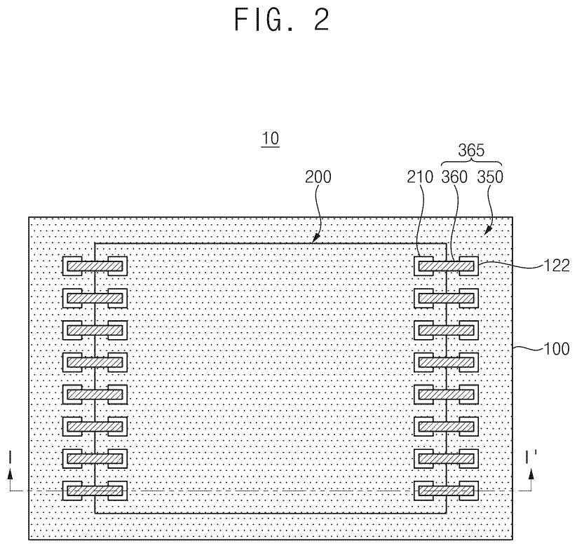

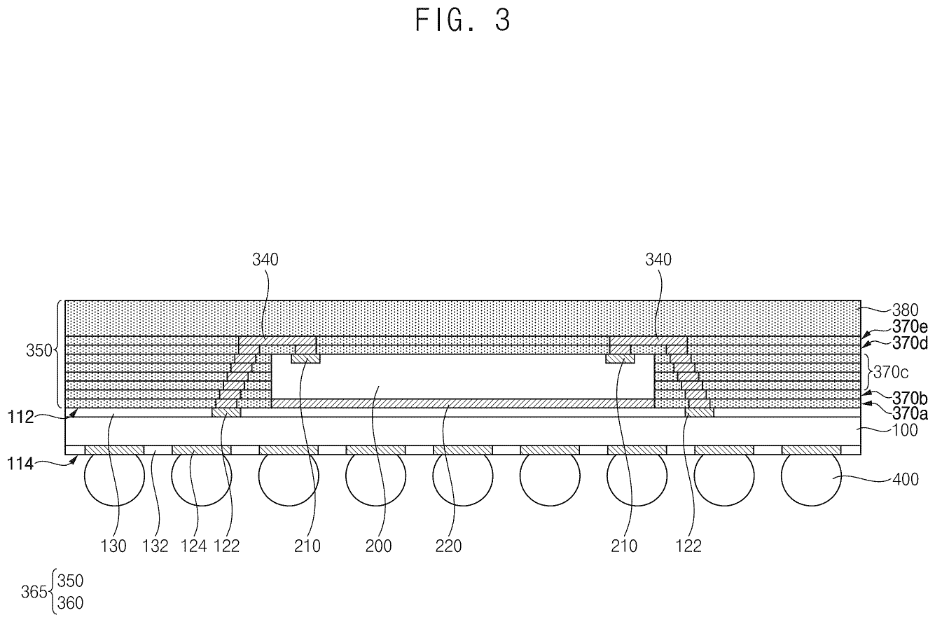

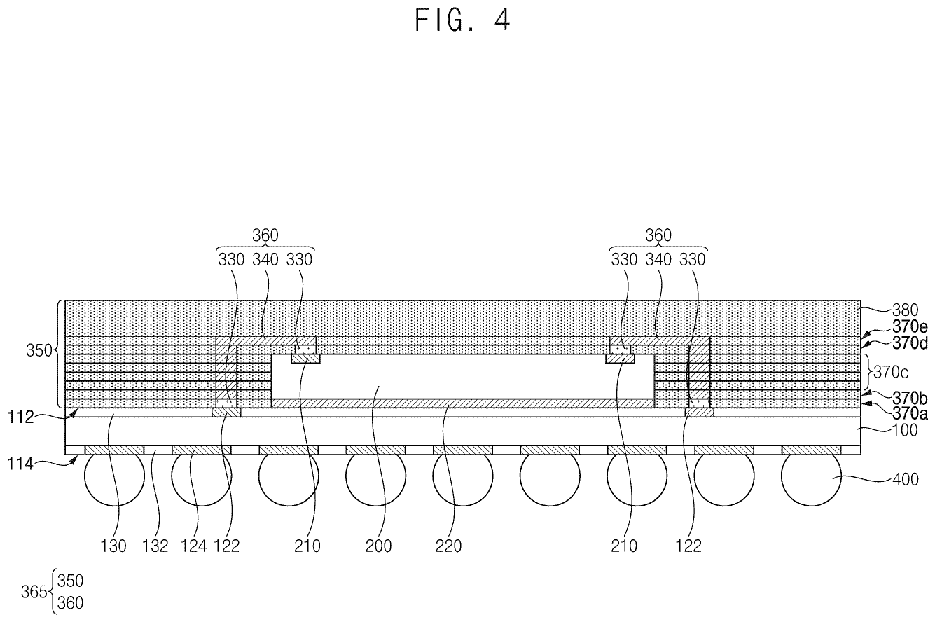

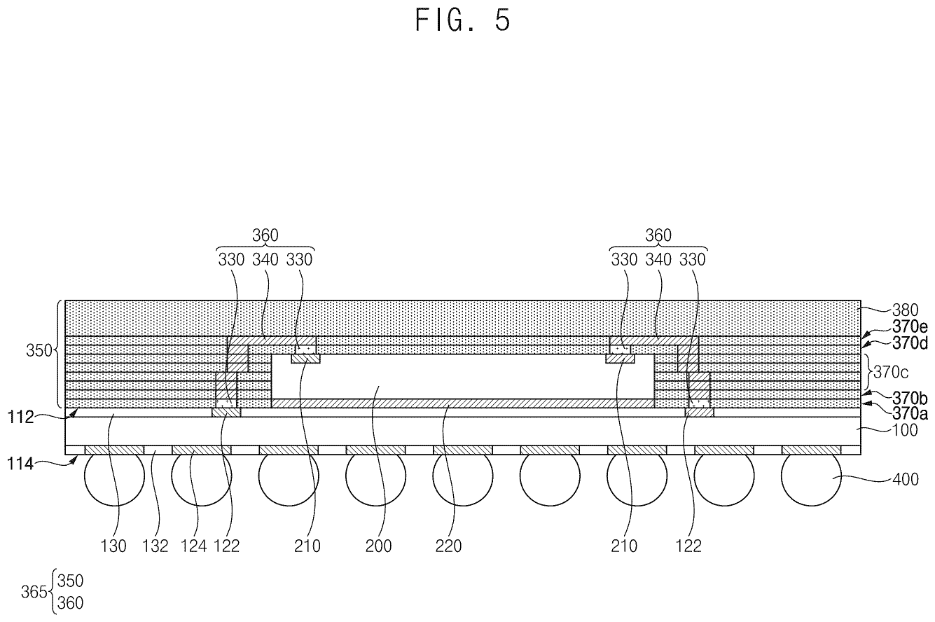

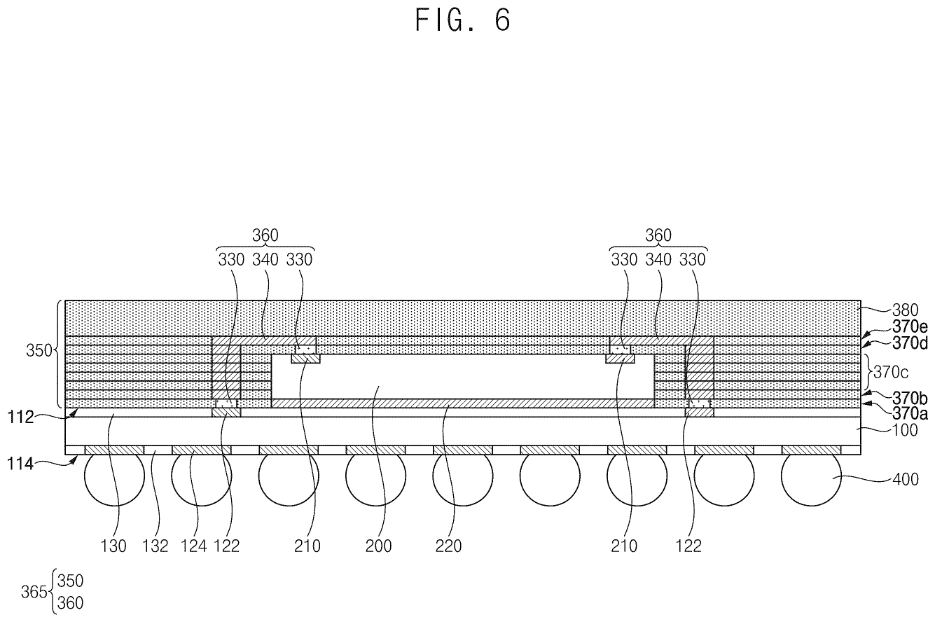

FIG. 1 is a cross-sectional view illustrating a semiconductor package according to one or more example embodiments. FIG. 2 is a plan view illustrating a semiconductor package according to one or more example embodiments. FIG. 3 is a cross-sectional view illustrating a semiconductor package according to one or more example embodiments. FIG. 4 is a cross-sectional view illustrating a semiconductor package according to one or more example embodiments. FIG. 5 is a cross-sectional view illustrating a semiconductor package according to one or more example embodiments. FIG. 6 is a cross-sectional view illustrating a semiconductor package according to one or more example embodiments.

FIG. 1 is a cross-sectional view taken along line I-I′ of FIG. 2.

Referring to one or more example embodiments shown in FIGS. 1 and 2, the semiconductor package 10 may include a package substrate 100, at least one semiconductor chip 200 disposed on the package substrate 100, and a powder layer stacked structure 365. The powder layer stacked structure 365 may include a molding structure and a bonding wire powder structure 360. The semiconductor package 10 may further include an adhesive layer 220 and an external connection member 400.

According to one or more example embodiments, it is described that one semiconductor chip (i.e., a first semiconductor chip) may be disposed on the package substrate 100, but one or more example embodiments may not be limited thereto. For example, two or more semiconductor chips may be stacked on the package substrate 100.

The package substrate 100 may be, e.g., a printed circuit board (PCB). The printed circuit board may be a multilayer circuit board having various circuit patterns therein, such as transistors, wirings, vias, contact plugs, conductive pads, etc.

In one or more example embodiments, the circuit patterns may include first substrate pads 122 at a first surface 112 of the package substrate 100 and second substrate pads 124 at a second surface 114 of the package substrate 100.

A first substrate protective layer 130 may be disposed at the first surface 112 of the package substrate 100 and may extend from sides of the first substrate pads 122 in a lateral direction. A second substrate protective layer 132 may be disposed at the second surface 114 of the package substrate 100 and may extend from sides of the second substrate pads 124 in the lateral direction. The first and second substrate protective layers 130 and 132 may include an insulation material.

An upper surface of the first substrate pad 122 may be exposed from the first substrate protective layer 130, and may not be covered by the first substrate protective layer 130. A bottom surface of the second substrate pads 124 may be exposed from the second substrate protective layer 132, and may not be covered by the second substrate protective layer 132 on the second surface 114 of the package substrate 100. In one or more example embodiments, the first substrate pads 122 may be disposed adjacent to opposite edges of the package substrate 100.

The first substrate pads 122 may be provided for electrical signal transmission with the first semiconductor chip 200 mounted on the package substrate 100. For example, the first substrate pads 122 may serve as bonding pads. The second substrate pads 124 may be for electrical signal transmission with a module substrate disposed below, and the second substrate pads 124 may serve as an external connection pad.

The external connection member 400 may contact the bottom surface of one of the second substrate pads 124.

The first and second substrate pads 122 and 124 may include metal, e.g., copper, aluminum, or nickel, etc. The external connection member 400 may include solder, e.g., an alloy of tin, silver, copper, or lead, etc.

The first semiconductor chip 200 may be a circuit device such as a logic device or a memory device. The memory device may be a volatile memory device such as a Dynamic Random Access Memory (DRAM) device or a Static Random Access Memory (SRAM) device, or a non-volatile memory device such as a flash memory device or an Electrically Erasable Programmable Read-Only Memory (EEPROM) device.

The first semiconductor chip 200 may include circuit patterns formed on a first surface of a first semiconductor substrate and an insulation layer covering the circuit patterns. First chip pads 210 may be disposed on the first surface of the first semiconductor substrate. The first chip pads 210 may be electrically connected to the circuit patterns formed on the first surface of the first semiconductor substrate.

In one or more example embodiments, the first chip pads 210 may be adjacent to an edge of the first semiconductor substrate.

The adhesive layer 220 may be interposed between the first semiconductor chip 200 and the package substrate 100. The first semiconductor chip 200 may be adhered on an upper surface of the package substrate 100 using the adhesive layer 220. The first chip pads 210 included in the first semiconductor chip 200 may be disposed adjacent to the first substrate pads 122 included in the package substrate 100.

For example, the adhesive layer 220 may include an adhesive material such as die attach layer (DAF).

The powder layer stacked structure 365 may include powder layers 370a, 370b, 370c, 370d, and 370e stacked in a vertical direction and an upper molding layer 380 disposed on an uppermost powder layer 370e. The powder layer stacked structure 365 may cover the first semiconductor chip 200. Each of the powder layers 370a, 370b, 370c, 370d, and 370e may include metal powder layers 330 and 340 and a molding layer 350 arranged in a horizontal direction. According to one or more example embodiments, the upper molding layer 380 may include only the molding layer.

The metal powder layers 330 and 340 included in each of the powder layers 370a, 370b, 370c, 370d, and 370e may be an aggregate of sintered metal powders, and the molding layer 350 may be an aggregate of sintered molding powders. The molding layer 350 included in each of the powder layers 370a, 370b, 370c, 370d, and 370e may contact sidewalls of the metal powder layers 330 and 340, so that the metal powder layers 330 and 340 may be supported by the molding layer 350. The molding powder may be a thermosetting resin powder, e.g., an epoxy mold compound (EMC) powder.

The molding layers 350 included in each of the powder layers 370a, 370b, 370c, 370d, and 370e may each include the same material, so that the molding layers 350 may be treated as one molding layer 350. In one or more example embodiments, at least one of the molding layers 350 included in each of the powder layers 370a, 370b, 370c, 370d, and 370e may include different materials.

The metal powder layers 330 and 340 included in the powder layer stacked structure 365 may serve as a bonding wire powder structure 360, and the molding layer 350 included in the powder layer stacked structure 365 may serve as a molding structure.

The bonding wire powder structure 360 may have a connected wiring structure. Both ends of the bonding wire powder structure 360 may contact the first substrate pad 122 included in the package substrate 100 and the first chip pad 210 included in the first semiconductor chip 200, respectively. The bonding wire powder structure 360 may electrically connect the first substrate pad 122 and the first chip pad 210. A plurality of bonding wire powder structures 360 may be disposed on the package substrate 100.

Each of the metal powders layer included in the bonding wire powder structure 360 may include at least one of a first bonding layer 330 and a first metal layer 340.

In one or more example embodiments, the first bonding layers 330 may be disposed only on the upper surface of the first substrate pad 122 and an upper surface of the first chip pad 210, respectively, and may directly contact the upper surface of the first substrate pad 122 and the upper surface of the first chip pad 210. The first bonding layer 330 may be an aggregate of sintered bonding powders, and the bonding powder may include a first metal.

The first metal layers 340 are disposed on the first bonding layer 330, and a stacked structure of the first metal layers 340 may be connected to the first bonding layers 330. The first metal layers 340 may be an aggregate of sintered metal powders, and the metal powder may include a second metal.

The metal powder layers 330 and 340 included in the bonding wire powder structure 360 may include the same material or different materials depending on stacked positions of the metal powder layers 330 and 340.

In one or more example embodiments, as shown in FIGS. 1 and 4, 5 and 6, the first bonding layer 330 and the first metal layer 340 may include different materials. In one or more example embodiments, the first metal layer 340 may include a material having a resistance lower than a resistance of the first bonding layer 330.

In one or more example embodiments, the first bonding layer 330 and the first metal layers 340 may include, e.g., copper (Cu), aluminum (Al), tungsten (W), nickel (Ni), molybdenum (Mo), and gold (Au), silver (Ag), chromium (Cr), tin (Sn), titanium (Ti), lead (Pb), etc.

The first bonding layer 330 may include a metal having excellent bonding properties with the first substrate pad 122. The first bonding layer 330 may include, e.g., lead (Pb). According to one or more example embodiments, the first metal layers 340 may include, e.g., gold (Au) or silver (Ag).

In one or more example embodiments, as shown in FIG. 3, the first bonding layer 330 and the first metal layer 340 may include the same material. According to one or more example embodiments, the first bonding layer 330 and the first metal layer 340 may not be distinguishable from each other.

The bonding wire powder structure 360 may include a first portion contacting the first substrate pad 122, a second portion contacting the first chip pad 120, and a third portion for connecting between the first and second portions.

Shapes of the portions of the bonding wire powder structure 360 may not be limited. For example, according to one or more example embodiments, the bonding wire powder structure 360 may be formed so that a length or a height of a connecting line from the first substrate pad 122 to the first chip pad 120 may be decreased. In the bonding wire powder structure 360, a position and a shape of a wiring may change depending on positions of the metal powders.

In one or more example embodiments, as shown in FIGS. 1 and 3, 4, 5 and 6, in the third portion, at least a portion located higher than the upper surface of the first chip pad 210 may be flat to face the upper surface of the package substrate 100.

In one or more example embodiments, as shown in FIGS. 1 and 3, at least a portion of the third portion may have an inclination (i.e., may not have a vertical inclination) with respect the upper surface of the package substrate 100.

In one or more example embodiments, as shown in FIGS. 4, 5 and 6, at least a portion of the third portion may have a vertical inclination with respect to the upper surface of the package substrate 100. As shown in FIGS. 4, 5 and 6, the bonding wire powder structure 360 may include a portion extending in the vertical direction from the upper surface of the first substrate pad 122. As shown in FIG. 5, in the bonding wire powder structure 360, edges of portions extending in the vertical direction from the upper surface of the first substrate pad 122 may have a step shape.

In one or more example embodiments, in the cross-sectional view, a width of the first portion of the bonding wire powder structure 360 may be equal to a width of the third portion of the bonding wire powder structure 360, or may be less than the width of the third portion of the bonding wire powder structure 360. In the following description, in the cross-sectional view, the width of the bonding wire powder structure 360 may correspond to a width of a wiring line of the bonding wire powder structure 360. For example, as shown in FIGS. 1 and 3, 4 and 5, a width of the first bonding layer 330 may be the same as a width of the first metal layer 340. Alternatively, as shown in FIG. 6, the width of the first bonding layer 330 may be less than the width of the first metal layer 340.

Bonding balls having a width greater than a width of the third portion may not be disposed on the first and second portions of the bonding wire powder structure 360.

If the bonding ball may be disposed between the first portion of the bonding wire powder structure 360 and the first chip pad 210, the bonding ball may have a diameter greater than a diameter of the third portion of the bonding wire powder structure 360. Further, a size of the first chip pad 210 may be greater than a size of the bonding ball. Therefore, it may be difficult to reduce the size of the first chip pad 210. However, because the bonding wire powder structure 360 according to the example embodiment may not include the bonding balls, the width of the edge of the bonding wire powder structure 360 may be decreased. Thus a size of the first chip pad 210 may be decreased.

The first chip pad 210 may be designed to have a size greater than a size of the first portion of the bonding wire powder structure 360. In one or more example embodiments, the first portion of the bonding wire powder structure 360 may cover about 60% to about 95% of an upper surface of the first chip pad 210. The first bonding layer 330 may cover about 60% to about 95% of the upper surface of the first chip pad 210.

As the first chip pad 210 may be formed without considering the size of the bonding ball, the size of the first chip pad 210 may be decreased compared to a case where the bonding ball may be included. Accordingly, the size of the first semiconductor chip 200 may be decreased.

In one or more example embodiments, the bonding wire powder structure 360 may have the same width (i.e., width in the cross-sectional view) depending on a position thereof. For example, as shown in FIGS. 1 and 3, 4 and 5, the first, second and third portions of the bonding wire powder structure 360 may have the same width.

The upper molding layer 380 may be higher than an uppermost portion of the bonding wire powder structure 360. Accordingly, the molding structure may cover the bonding wire powder structure 360 and the first semiconductor chip 200.

As described above, the bonding wire powder structure 360 may have a stacked structure of the metal powder layers 330 and 340, which are sintered metal powder aggregates. Because the metal powder layers 330 and 340 may be supported by the mold layer 350, a moving (e.g., sweeping) toward one side of the bonding wire powder structures 360 contacting the first chip pads 210 may be decreased. Accordingly, a short defect, in which the bonding wire powder structures 360 contact each other, due the moving of the bonding wire powder structures 360, may be decreased.

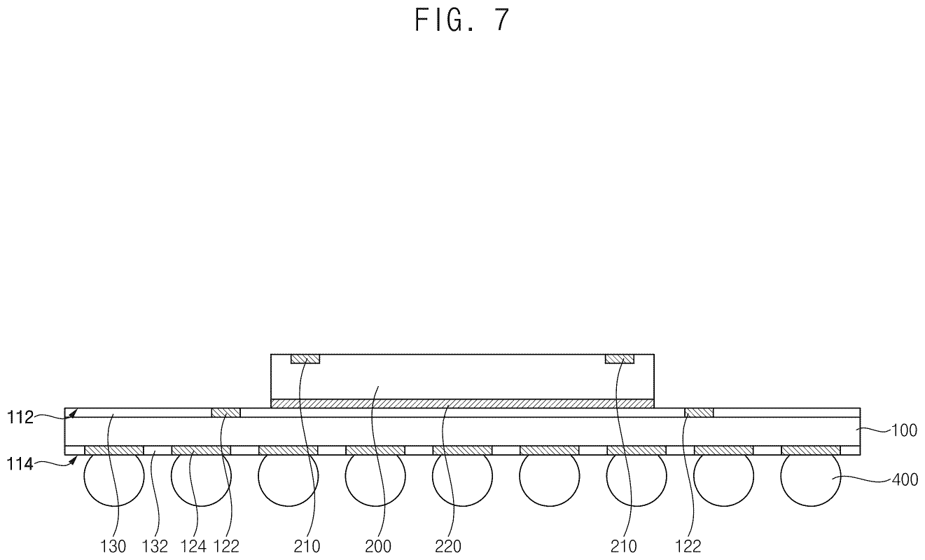

FIGS. 7, 8, 9, 10, 11, 12, 13, 14, 15, 16, 17, 18, 19 and 20 are cross-sectional views illustrating a method for manufacturing a semiconductor package according to one or more example embodiments.

Referring to one or more example embodiments shown in FIG. 7, a first semiconductor chip 200 may be mounted on a package substrate 100.

The package substrate 100 may be, e.g., a printed circuit board (PCB) or a multilayer circuit board having various circuit patterns therein. In one or more example embodiments, the circuit patterns may include first substrate pads 122 disposed at a first surface 112 of the package substrate 100, and second substrate pads disposed at a second surface 114 of the package substrate 100.

A first substrate protective layer 130 may be disposed at the first surface 112 of the package substrate 100 and may extend from sides of the first substrate pads 122. A second substrate protective layer 132 may be disposed at the second surface 114 of the package substrate 100 and may extend from sides of the second substrate pads 124.

The first semiconductor chip 200 may include circuit patterns on an upper surface of a first semiconductor substrate and insulation layers covering the circuit patterns. First chip pads 210 may be disposed on the upper surface of the first semiconductor substrate. The first chip pads 210 may be electrically connected to circuit patterns on the upper surface of the first semiconductor substrate.

An adhesive layer 220 may be formed on a bottom of the first semiconductor chip 200, and the bottom of the first semiconductor chip 200 and the first surface 112 of the package substrate 100 may be bonded to each other by the adhesive layer 220. According to one or more example embodiments, the first chip pads 210 included in the first semiconductor chip 200 may be disposed adjacent to the first substrate pads 122 included in the package substrate 100.

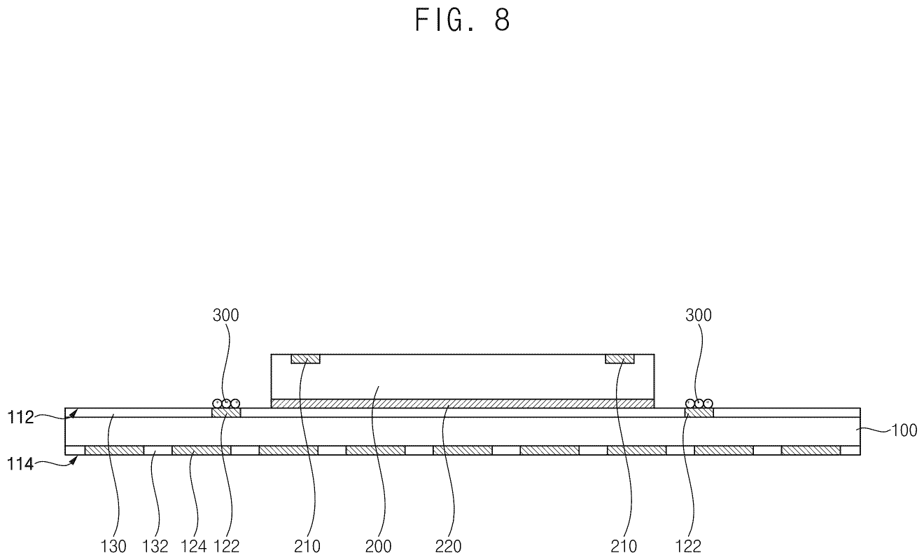

Referring to one or more example embodiments shown in FIG. 8, first metal powders including a first metal material may be selectively sprayed onto the upper surface of the first substrate pad 122. Accordingly, the first metal powders may be aggregated to form a bonding powder structure 300 on the upper surface of the first substrate pad 122. According to one or more example embodiments, the first metal powders may not be disposed on the first substrate protective layer 130 on sides of the first substrate pad 122.

In one or more example embodiments, the first metal powder may include copper (Cu), aluminum (Al), tungsten, nickel (Ni), molybdenum (Mo), gold (Au), silver (Ag), chromium (Cr), tin (Sn), titanium (Ti), or lead (Pb), etc.

In one or more example embodiments, the first metal powder may include a metal different from a metal included in a second metal powder subsequently formed. In one or more example embodiments, the first metal powder may be the same metal powder as the second metal powder subsequently formed. According to one or more example embodiments, the semiconductor package as shown in FIG. 3 may be manufactured by performing the same subsequent processes.

The bonding powder structure 300 may directly contact the first substrate pad 122. Therefore, the first metal powder may include the metal that has an excellent bonding property with the first substrate pad 122. For example, the first metal powder may include lead (Pb).

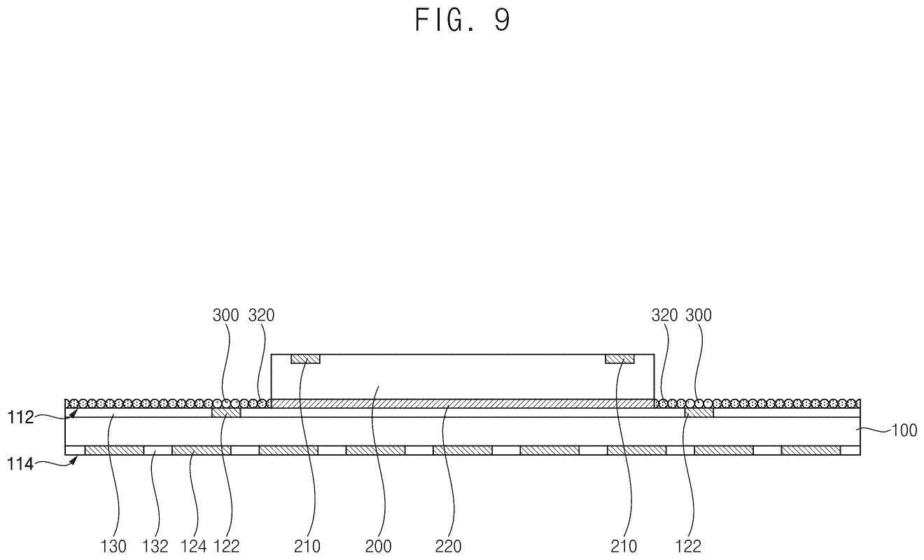

Referring to one or more example embodiments shown in FIG. 9, molding powders may be sprayed on the package substrate 100 from sides of the bonding powder structure 300. Accordingly, the molding powder may be aggregated to form a molding powder structure 320 on the upper surface of the package substrate 100. The molding powder structure 320 may be disposed on the first substrate pad 122 and the first substrate protective layer 130 outside the bonding powder structure 300.

The bonding powder structure 300 may be surrounded by the molding powder structure 320, and the molding powder structure 320 may contact the sides of the bonding powder structure 300. Accordingly, the bonding powder structure 300 may be supported by the molding powder structure 320. The molding powder structure 320 and the bonding powder structure 300 may be arranged in a horizontal direction to form one layer.

The molding powder may include thermosetting resin powder, e.g., epoxy mold compound (EMC) powder.

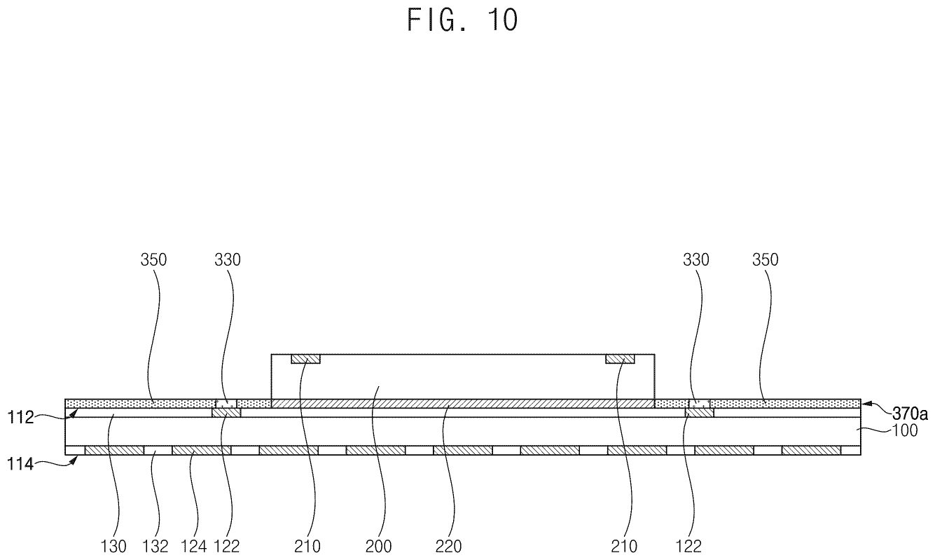

Referring to one or more example embodiments shown in FIG. 10, the molding powder structure 320 and the bonding powder structure 300 may be sintered to form a first powder layer 370a including a molding layer 350 and a first bonding layer 330.

For sintering of the molding powder structure 320 and the bonding powder structure 300, the molding powder structure 320 and the bonding powder structure 300 may be melted by applying heat, and then may be cooled. A heat source for the heating may include, e.g., a laser.

The first powder layer 370a may cover the first surface 112 of the package substrate 100. In the first powder layer 370a, the molding layer 350 and the first bonding layer 330 may be arranged in the horizontal direction. In the first powder layer 370a, the first bonding layer 330 may be surrounded by the molding layer 350, and the first bonding layer 330 may be supported by the molding layer 350.

The first bonding layer 330 may contact the upper surface of the first substrate pad 122. The molding layer 350 may contact sidewalls of the first bonding layer 330. An upper surface of the first bonding layer 330 may be exposed from the molding layer 350, and may not be covered by the molding layer 350.

The molding layer 350 included in the first powder layer 370a may contact sidewalls of the first semiconductor chip 200.

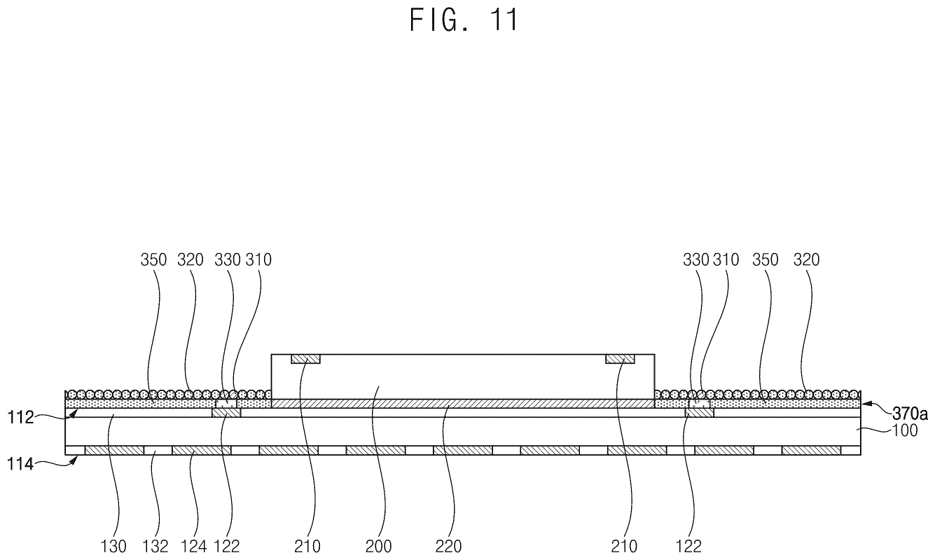

Referring to one or more example embodiments shown in FIG. 11, second metal powders including a second metal material may be selectively sprayed on an upper surface of the first bonding layer 330. Accordingly, the second metal powders may be aggregated to form the first metal powder structure 310. According to one or more example embodiments, the second metal powders may not be disposed on the molding layer 350 outside the side of the first bonding layer 330.

The second metal powder may include a metal having low resistance. In one or more example embodiments, the second metal powder may include, e.g., copper (Cu), aluminum (Al), tungsten, nickel (Ni), molybdenum (Mo), gold (Au), silver (Ag), chromium (Cr), tin (Sn), titanium (Ti), or lead (Pb), etc.

In one or more example embodiments, the second metal powder may include a metal different from the metal included in the first metal powder. The second metal powder may include a metal having lower resistance than the metal included in the first metal powder. For example, the first metal powder may include lead (Pb), and the second metal powder may include gold (Au) or silver (Ag).

In one or more example embodiments, the second metal powder may include a metal which is the same as the metal included in the first metal powder. The second metal powder and the first metal powder may include, e.g., gold (Au) or silver (Ag).

Thereafter, the molding powders may be sprayed on the first powder layer 370a from sides of the first metal powder structure 310. Accordingly, the molding powder may be aggregated to form the molding powder structure 320 on the upper surface of the first powder layer 370a.

The first metal powder structure 310 may be surrounded by the molding powder structure 320, and the molding powder structure 320 may contact sidewalls of the first metal powder structure 310. Accordingly, the first metal powder structure 310 may be supported by the molding powder structure 320. The molding powder structure 320 and the first metal powder structure 310 may be arranged in the horizontal direction to form one layer.

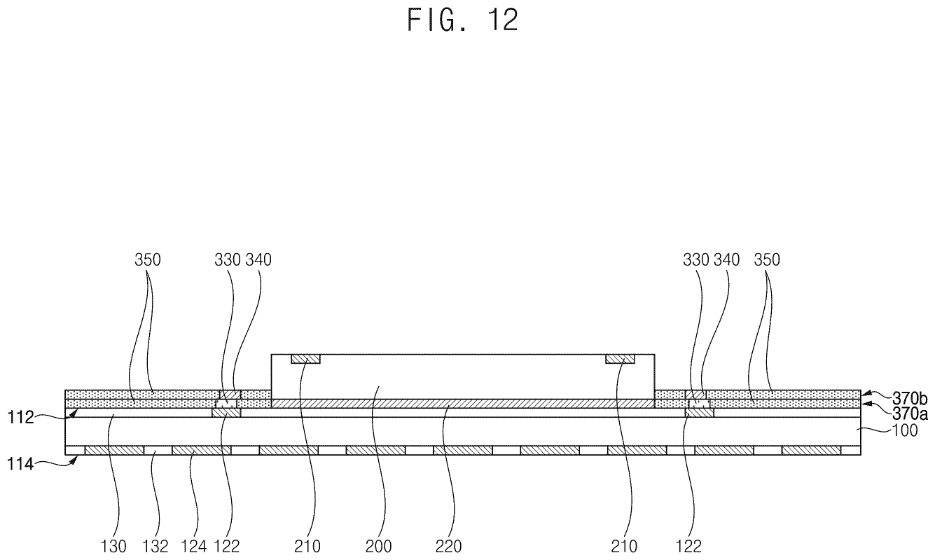

Referring to one or more example embodiments shown in FIG. 12, the molding powder structure 320 and the first metal powder structure 310 may be sintered to form a second powder layer 370b including the molding layer 350 and a first metal layer 340.

The second powder layer 370b may cover the upper surface of the first powder layer 370a, and may contact the first powder layer 370a. The molding layers 350 included in each of the first and second powder layers 370b may include the same material. At least a portion of the first bonding layer 330 in the first powder layer 370a may contact the first metal layer 340 in the second powder layer 370b, and thus the first bonding layer 330 in the first powder layer 370a and the first metal layer 340 in the second powder layer 370b may be electrically connected to each other.

In the second powder layer 370b, the molding layer 350 and the first metal layer 340 may be arranged in the horizontal direction. In the second powder layer 370b, the first metal layer 340 may be surrounded by the molding layer 350, and thus the first metal layer 340 may be supported by the molding layer 350. The molding layer 350 may contact sidewalls of the first metal layer 340. An upper surface of the first metal layer 340 may be exposed from the molding layer 350, and may not be covered by the molding layer 350.

The molding layer 350 included in the second powder layer 370b may contact the sidewalls of the first semiconductor chip 200.

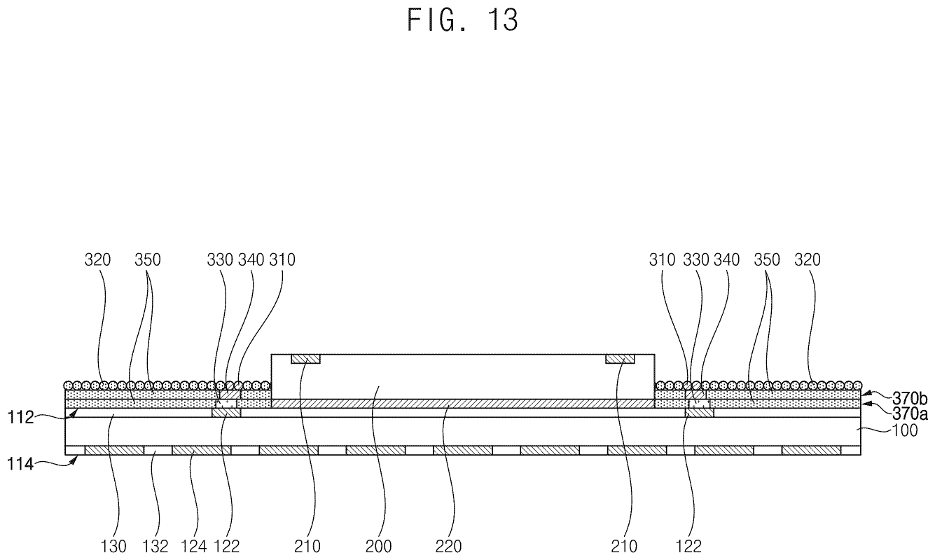

Referring to one or more example embodiments shown in FIG. 13, the second metal powders including the second metal material may be selectively sprayed on the upper surface of the first metal layer 340. Accordingly, the second metal powder may be aggregated to form the first metal powder structure 310 on the upper surface of the first metal layer 340. The second metal powder may not be disposed on the molding layer 350.

Thereafter, the molding powders may be sprayed on the second powder layer 370b from sides of the first metal powder structure 310. Accordingly, the molding powder may be aggregated to form the molding powder structure 320 on an upper surface of the second powder layer 370b.

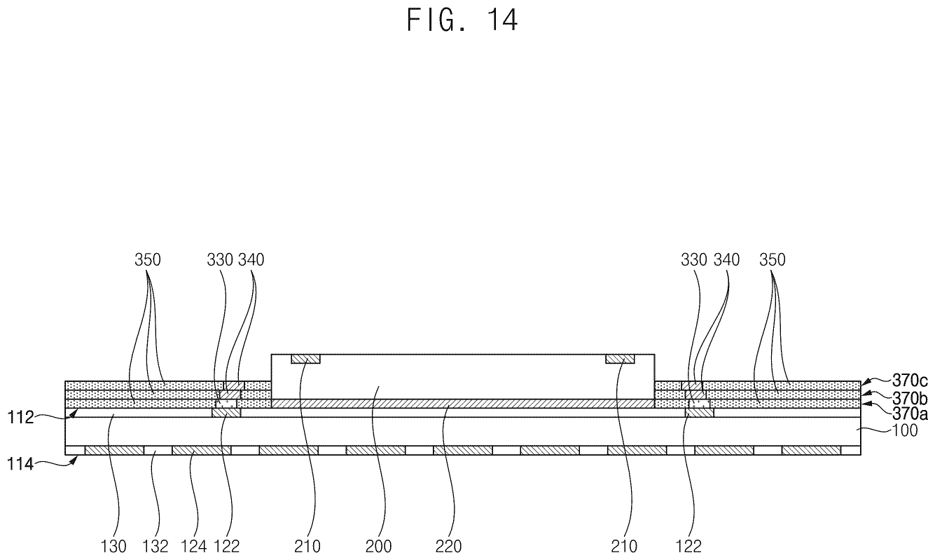

Referring to one or more example embodiments shown in FIG. 14, the molding powder structure 320 and the first metal powder structure 310 may be sintered to form a third powder layer 370c including the molding layer 350 and the first metal layer 340.

The third powder layer 370c may cover the upper surface of the second powder layer 370b, and may contact the second powder layer 370b. The molding layers 350 included in the first, second and third powder layers 370a, 370b, and 370c may include the same material. The first metal layers 340 in the second and third powder layers 370b and 370c may include the same material, and at least one portion of the first metal layers 340 may contact each other. Therefore, the first metal layers 340 may be electrically connected to each other. The first metal layers 340 may be stacked in the vertical direction.

In the third powder layer 370c, the molding layer 350 and the first metal layer 340 may be arranged in the horizontal direction. In the third powder layer 370c, the first metal layer 340 may be surrounded by the molding layer 350, and the first metal layer 340 may be supported by the molding layer 350. The molding layer 350 may contact the sidewall of the first metal layer 340. The upper surface of the first metal layer 340 may be exposed from the molding layer 350, and may not be covered by the molding layer 350.

The molding layer 350 included in the third powder layer 370c may contact the sidewall of the first semiconductor chip 200.

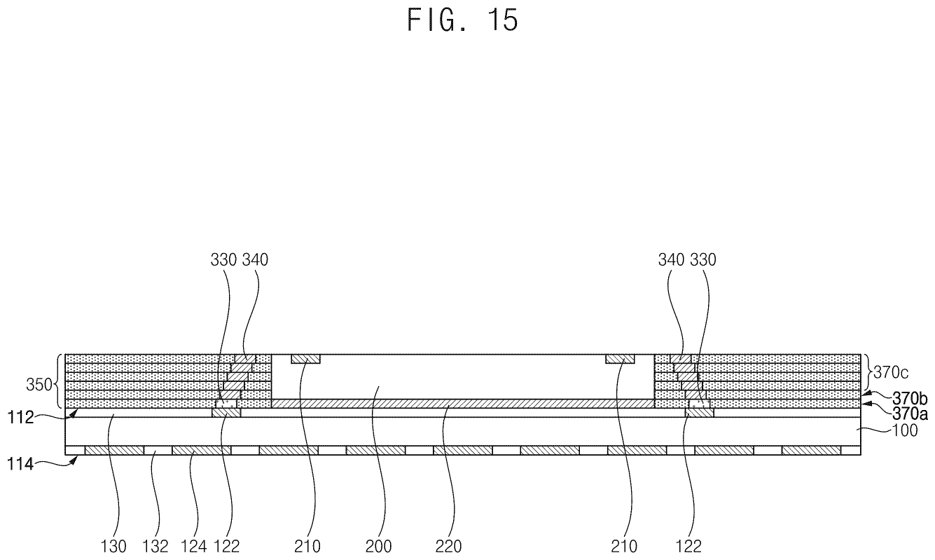

Referring to one or more example embodiments shown in FIG. 15, the processes described with reference to one or more example embodiments shown in FIGS. 13 and 14 may be repeatedly performed to form a plurality of third powder layers 370c stacked.

An upper surface of an uppermost third powder layer 370c may be substantially coplanar with an upper surface of the first semiconductor chip 200. Alternatively, the upper surface of the uppermost third powder layer 370c may be slightly lower than the upper surface of the first semiconductor chip 200.

Each of the third powder layers 370c may include the molding layer 350 and the first metal layer 340. The first metal layers 340 included in adjacent third powder layers 370c in the vertical direction may be at least partially contact with each other. The first metal layers 340 included in the third powder layers 370c may be stacked in the vertical direction, and may be connected to each other.

The molding layers 350 included in the first, second and third powder layers 370a, 370b, and 370c may include the same material, and thus the molding layers 350 may be merged into one molding layer 350. The first bonding layers 330 and the first metal layers 340 in the first, second and third powder layers 370c may be connected to each other to have a single linear shape, and may contact the first substrate pad 122.

In one or more example embodiments, at least one of the molding layers 350 included in in the first, second and third powder layers 370a, 370b, and 370c may include a different material.

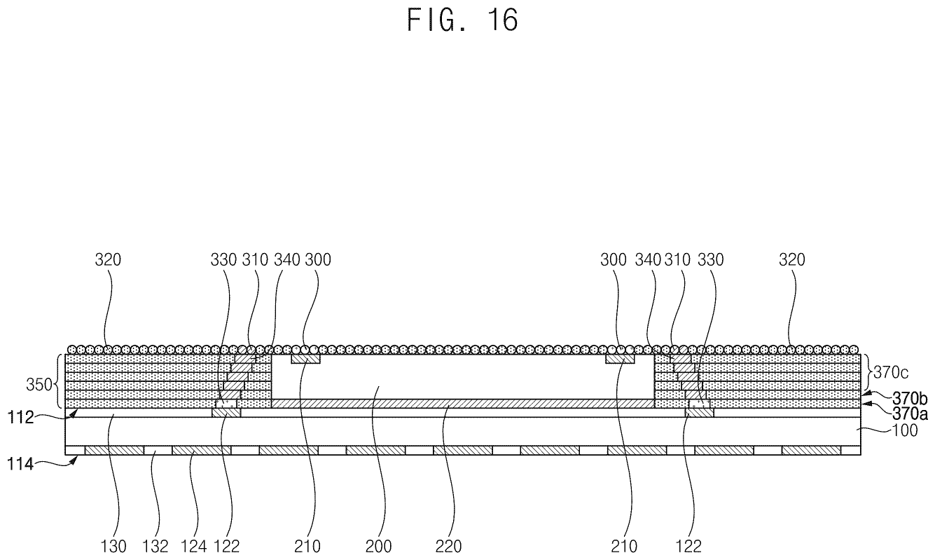

Referring to one or more example embodiments shown in FIG. 16, the first metal powders including the first metal material may be sprayed on the first chip pad 210 of the first semiconductor chip 200. Accordingly, the first metal powders may be aggregated to form the bonding powder structure 300 on an upper surface of the first chip pad 210.

The second metal powders including the second metal may be sprayed on the first metal layer 340 of the uppermost third powder layer 370c. Accordingly, the first metal powder structure 310 may be disposed on the first metal layer 340.

Additionally, the molding powders may be sprayed on the uppermost third powder layer 370c and the upper surface of the first semiconductor chip 200 outside the bonding powder structure 300 and the first metal powder structure 310. Accordingly, the molding powder structure 320 may be disposed on the uppermost third powder layer 370c and the upper surface of the first semiconductor chip 200.

The molding powder structure 320, the bonding powder structure 300, and the first metal powder structure 310 may be arranged in the horizontal direction to form one layer.

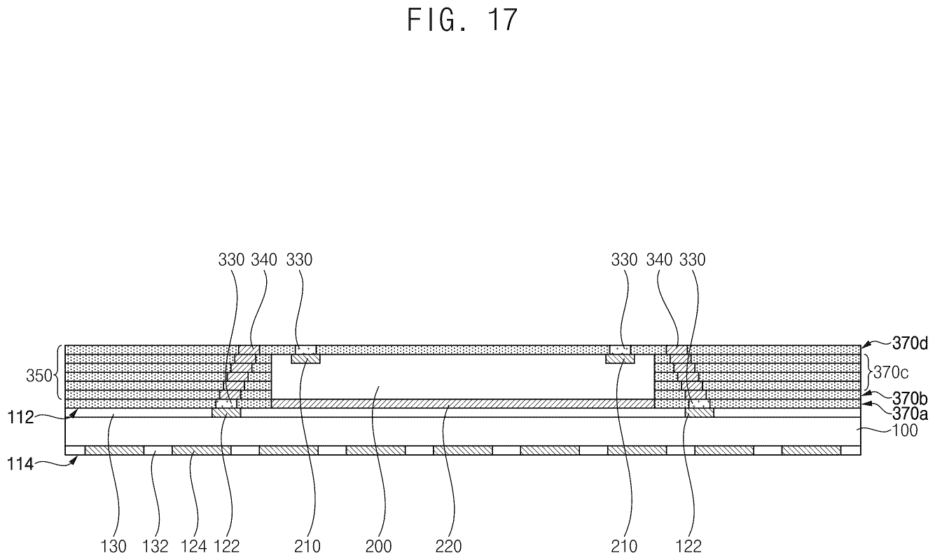

Referring to one or more example embodiments shown in FIG. 17, the molding powder structure 320, the bonding powder structure 300, and the first metal powder structure 310 may be sintered to form a fourth powder layer 370d including the molding layer 350, the first bonding layer 330, and the first metal layer 340.

The fourth powder layer 370d may cover an uppermost third powder layer 370c and the upper surface of the first semiconductor chip 200. The upper surfaces of the first bonding layer 330 and the first metal layer 340 in the fourth powder layer 370d may be exposed from the molding layer 350, and may not be covered by the molding layer 350.

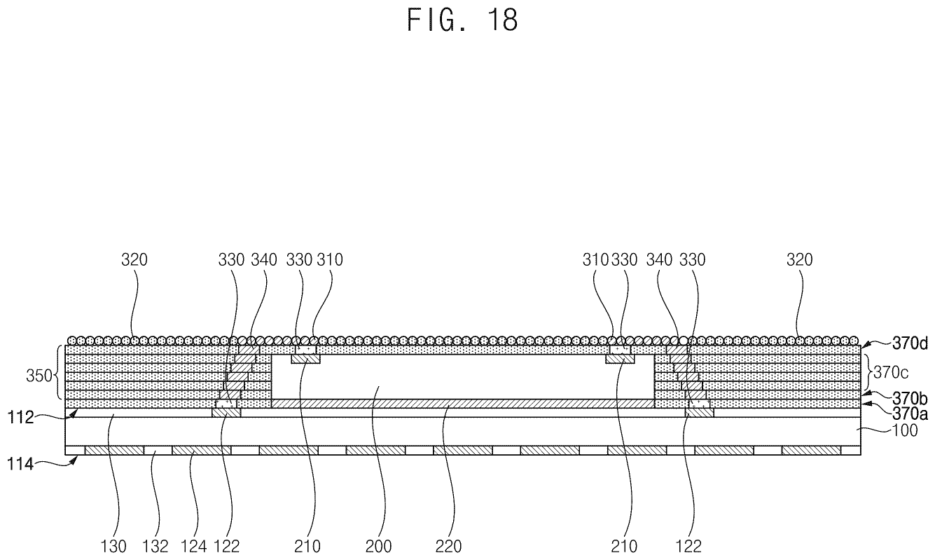

Referring to one or more example embodiments shown in FIG. 18, the second metal powders including the second metal material may be sprayed on a portion of the fourth powder layer 370d. The second metal powders may be disposed on the upper surfaces of the first bonding layer 330 and the first metal layer 340, and the upper surface of the molding layer 350 between the first bonding layer 330 and the first metal layer 340. Accordingly, the first metal powder structure 310 may be formed on the upper surfaces of the first bonding layer 330 and the first metal layer 340, and the upper surface of the molding layer 350 between the first bonding layer 330 and the first metal layer 340.

Additionally, the molding powders may be sprayed on the molding layer 350 of the fourth powder layer 370d from the side of the first metal powder structure 310 to form a molding powder structure 320.

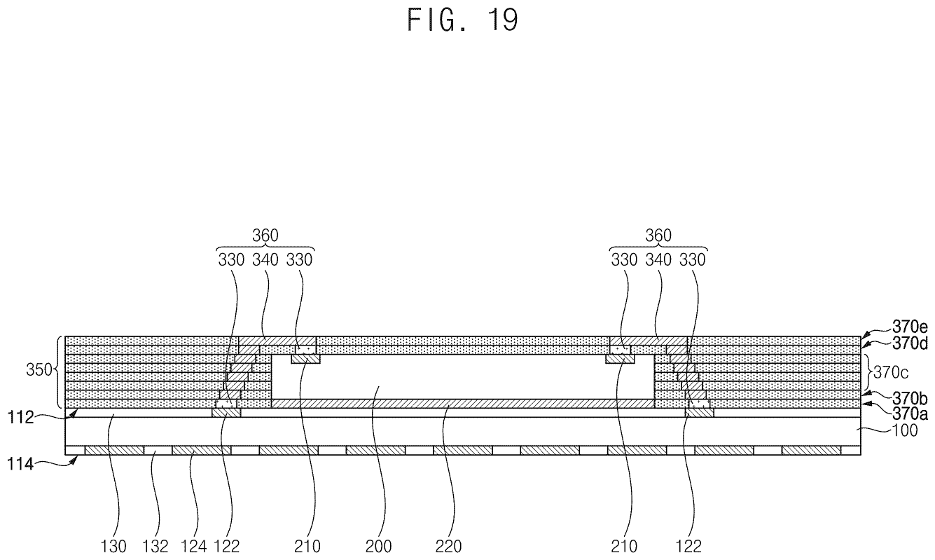

Referring to one or more example embodiments shown in FIG. 19, the molding powder structure 320 and the first metal powder structure 310 may be sintered to form a fifth powder layer 370e including the molding layer 350 and the first metal layer 340.

The first bonding layers 330 and the first metal layers 340 included in the first, second, third, fourth and fifth powder layers 370a, 370b, 370c, 370d, and 370e may be connected to each other to form a bonding wire powder structure 360 having a linear shape. The bonding wire powder structure 360 may electrically connect the first substrate pad 122 and the first chip pad 210.

In the processes for forming the first, second, third, fourth and fifth powder layers 370a, 370b, 370c, 370d, and 370e, arrangements of the first metal powders and the second metal powders may be changed. Therefore, a shape of the bonding wire powder structure 360 may be changed.

In one or more example embodiments, the first metal layers 340 included in the second and third powder layers 370b and 370c may be stacked to have an inclination (e.g., not a vertical inclination). The first metal layers 340 may be stacked to have the inclination in a direction toward the first chip pad 210. According to one or more example embodiments, one of the semiconductor packages shown in FIGS. 1 and 3 may be formed by subsequent processes.

In one or more example embodiments, the first metal layers 340 included in the second and third powder layers 370b and 370c may be vertically stacked from the first surface 112 of the package substrate 100. According to one or more example embodiments, one of the semiconductor packages shown in FIGS. 4, 5 and 6 may be manufactured by subsequent processes.

In one or more example embodiments, edges of the first metal layers 340 included in the second and third powder layers 370b and 370c may have a step shape. According to one or more example embodiments, the semiconductor package shown in FIG. 5 may be formed by subsequent processes.

In one or more example embodiments, the first metal layers 340 included in the second and third powder layers 370b and 370c may have the same width. According to one or more example embodiments, a width of the first bonding layer 330 may be the same as or less than a width of the first metal layers 340 included in the second and third powder layers 370b and 370c.

In one or more example embodiments, at least one of the first metal layers 340 included in the second and third powder layers 370b and 370c may have a different width. According to one or more example embodiments, the width of the first bonding layer 330 may be the same as a width of at least one of the first metal layers 340 included in the second and third powder layers 370b and 370c, or may be less than the width of at least one of the first metal layers 340.

The bonding wire powder structure 360 may include a first portion bonding the first substrate pad 122, a second portion bonding the first chip pad 210, and a third portion between the first and second portions.

In one or more example embodiments, in the cross-sectional view, a width of each of the first and second portions of the bonding wire powder structure 360 may be equal to or less than a width of the third portion of the bonding wire powder structure 360.

Additionally, the second portion of the bonding wire powder structure 360 may have a size similar to or slightly less than a size of the first chip pad 210. For example, the first bonding layer 330 of the bonding wire powder structure 360 may have a size of about 60% to about 95% of the upper surface of the first chip pad 210.

In one or more example embodiments, in the bonding wire powder structure 360, a portion disposed above the upper surface of the first chip pad 210 may include a flat portion facing the first surface 112 of the package substrate 100. An uppermost portion of the bonding wire powder structure 360 may extend in the horizontal direction parallel to the first surface 112 of the package substrate 100.

As described above with reference to one or more example embodiments, in the processes for forming the first, second, third, fourth and fifth powder layers 370a, 370b, 370c, 370d, and 370e, the bonding wire powder structure 360 having a target structure may be formed by changing the arrangements of the first metal powders and the second metal powders.

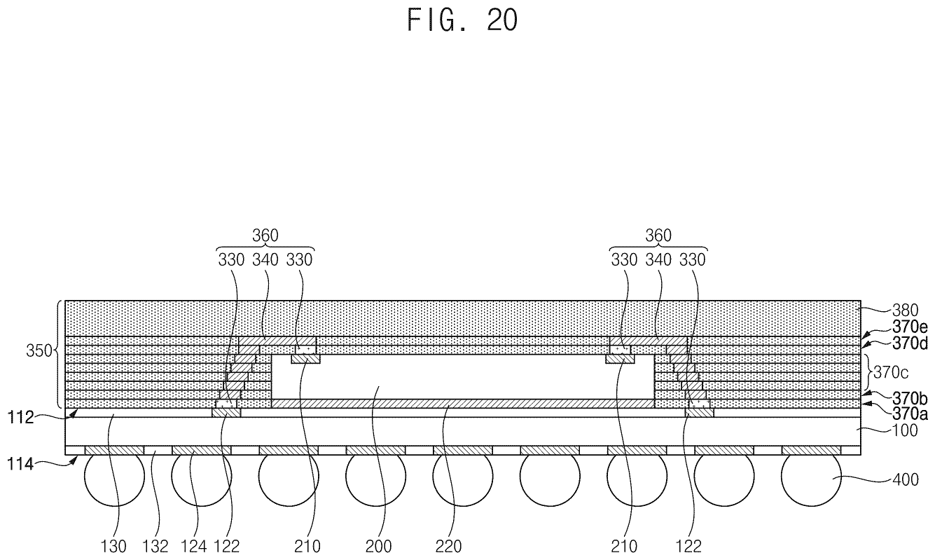

Referring to one or more example embodiments shown in FIG. 20, the molding powders may be sprayed on the fifth powder layer 370e to form the molding powder structure covering the fifth powder layer 370e. Thereafter, the molding powder structure may be sintered to form an upper molding layer 380. The upper molding layer 380 may not include the first metal layer 340 or the first bonding layer 330. An external connection member 400 may be formed on a bottom of the second substrate pads 124.

The first, second, third, fourth and fifth powder layers 370a, 370b, 370c, 370d, and 370e and the upper molding layer 380 may be formed on the package substrate 100.

The molding layer 350 and the upper molding layer 380 included in the first, second, third, fourth and fifth powder layers 370a, 370b, 370c, 370d, and 370a may be merged to one molding structure. The bonding wire powder structure 360 may be disposed in the molding structure.

By performing the above process, the semiconductor package according to one or more example embodiments may be manufactured.

As described above, with reference to one or more example embodiments, the bonding wire powder structure 360 may be formed by the stacking and the sintering of conductive powder including metal, and the bonding wire powder structure 360 may be formed together during processes for forming the molding structure. The conductive powder constituting the bonding wire powder structure 360 may be bonded on the first substrate pad 122 and the first chip pad 210, respectively, and the conductive powders may be stacked.

Generally, a metal line serving as a bonding wire may be provided, and bonding balls having a width greater than a cross-sectional width of the metal line may be formed on the ends of the metal line, respectively. The bonding balls connected to the ends of the metal line may be boned on the first chip pad 210 and the first substrate pad 122, respectively, to form a bonding wire structure. Therefore, each of the first chip pad 210 and the first substrate pad 122 may have a size greater than a size of the bonding ball, so that a reduction of each of the first chip pad 210 and the first substrate pad 122 may be difficult. However, in the one or more example embodiments, the processes for forming the bonding ball may not be performed, and thus the width of each of the first and second portions of the bonding wire powder structure 360 may not be expanded greater than the width of the third portion. Accordingly, the size of the first chip pad 210 may be decreased to a level similar to a size of a contact area of the bonding wire powder structure 3

Generally, after performing the bonding process for bonding a bonding wire to the first substrate pad 122 and the first chip pad 210, a mold member may be formed to cover the first semiconductor chip 200 on the package substrate 100 by a molding process. When the molding process is performed, bonding wires may move (sweep) toward one side. Therefore, a short failure, in which the bonding wires contact each other, may occur. However, in the one or more example embodiments, the molding process and the process for forming the bonding wire powder structure 360 may be performed together. After forming the bonding wire powder structure 360, a forming of the mold member covering the bonding wire powder structure 360 may not be performed. Accordingly, the bonding wire powder structures 360 may not move, during the molding process, and a short defect between the bonding wire powder structures 360 may be decreased.

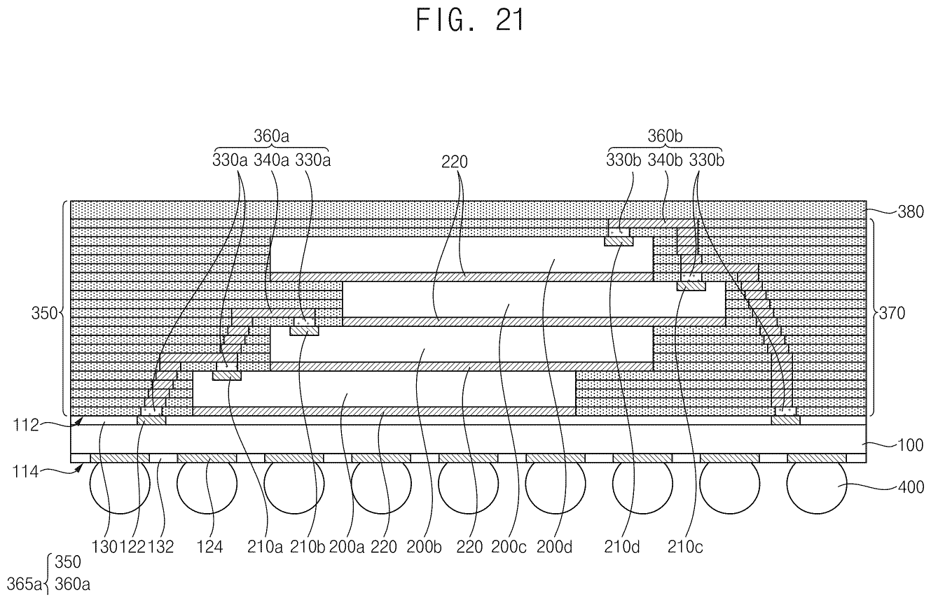

FIG. 21 is a cross-sectional view illustrating a semiconductor package according to one or more example embodiments.

The semiconductor package shown in FIG. 21 may include a plurality of semiconductor chips.

Referring to one or more example embodiments shown in FIG. 21, the semiconductor package may include the package substrate 100, a plurality of semiconductor chips 200a, 200b, 200c, and 200d disposed on the package substrate 100, and a powder layer stacked structure 365a. The powder layer stacked structure 365a may include a molding structure 350, a first bonding wire powder structure 360a, and a second bonding wire powder structure 360b. The semiconductor package may further include the adhesive layers 220 and the external connection member 400.

According to one or more example embodiments, the plurality of semiconductor chips may be described as first, second, third and fourth semiconductor chips 200a, 200b, 200c, and 200d.

The first, second, third and fourth semiconductor chips 200a, 200b, 200c, and 200d may be sequentially stacked on the package substrate 100. In a plan view, the first, second, third and fourth semiconductor chips 200a, 200b, 200c, and 200d may have a square shape. Each of the first, second, third and fourth semiconductor chips 200a, 200b, 200c, and 200d may have a first side and a second side facing the first side.

The first semiconductor chip 200a may include first chip pads 210a on a first surface of the first semiconductor substrate. The first chip pads 210a may be disposed on an edge adjacent to the first side of the first semiconductor chip 200a.

Each of the second, third and fourth semiconductor chips 200b, 200c, and 200d may have a structure substantially the same as or similar to a structure of the first semiconductor chip 200a. Second, third and fourth chip pads 210b, 210c, and 210d may be disposed in the second, third and fourth semiconductor chips 200b, 200c, and 200d, respectively.

The second semiconductor chip 200b may include second chip pads 210b on a first surface of the second semiconductor substrate. In one or more example embodiments, the second chip pad 210b may be disposed on an edge adjacent to the first side of the second semiconductor chip 200b. The second semiconductor chip 210b may be bonded on an upper surface of the first semiconductor chip 200a by an adhesive layer 220 attached below a second surface of the second semiconductor substrate.

A lower surface of the second semiconductor chip 200b may not contact an entire upper surface of the first semiconductor chip 200a, and only portions of the first and the second semiconductor chips 200a and 200b may contact each other.

In one or more example embodiments, the first and the second semiconductor chips 200a and 200b may be stacked in the vertical direction, and a sidewall of the second semiconductor chip 200b may not be aligned with a sidewall of the first semiconductor chip 200a. The first chip pads 210a included in the first semiconductor chip 200a may be exposed from the second semiconductor chip 200b, and may not be covered by the second semiconductor chip 200b.

In one or more example embodiments, the second semiconductor chip 200b may be stacked to be offset in a first direction, which is a horizontal direction, with respect to the first semiconductor chip 200a. According to one or more example embodiments, the second chip pads 210b may be adjacent the first chip pads 210a in the first direction, and the first and second chip pads 210a and 210b may be aligned in the first direction. Additionally, the second chip pads 210b may be adjacent to the first substrate pads 122 included in the package substrate 100.

The third semiconductor chip 200c may include third chip pads 210c on a first surface of the third semiconductor substrate. In one or more example embodiments, the third chip pad 210c may be disposed at an edge adjacent to the second side of the third semiconductor chip 200c. The third semiconductor chip 200c may be bonded on the upper surface of the second semiconductor chip 200b by an adhesive layer 220 below a second surface of the third semiconductor substrate.

A lower surface of the third semiconductor chip 200c may not contact an entire upper surface of the second semiconductor chip 200b, and only portions of the second and third semiconductor chips 200b and 200c may contact each other.

In one or more example embodiments, the second and third semiconductor chips 200b and 200c may be stacked in the vertical direction, and a sidewall of the third semiconductor chip 200c may not be aligned with the sidewall of the second semiconductor chip 200b. The second chip pads 210b included in the second semiconductor chip 200b may be exposed from the third semiconductor chip 200c, and may not be covered by the third semiconductor chip 200c.

In one or more example embodiments, the third semiconductor chip 200c may be stacked to be offset in the first direction with respect to the second semiconductor chip 200b. Additionally, the third chip pads 210c may be adjacent to the first substrate pads 122 included in the package substrate 100.

The fourth semiconductor chip 200d may include fourth chip pads 210d on a first surface of the fourth semiconductor substrate. In one or more example embodiments, the fourth chip pad 210d of the fourth semiconductor chip 200d may be disposed on an edge portion adjacent to the second side of the fourth semiconductor chip 200d. The fourth semiconductor chip 200d may be bonded on the upper surface of the third semiconductor chip 200c by an adhesive layer 220 attached below a second surface of the fourth semiconductor substrate.

A lower surface of the fourth semiconductor chip 200d may not entirely contact the upper surface of the third semiconductor chip 200c, and only portions of the third and fourth semiconductor chips 200c and 200d may contact each other.

In one or more example embodiments, the third and fourth semiconductor chips may be stacked in the vertical direction, and a sidewall of the fourth semiconductor chip 200d may not be aligned to the sidewall of the third semiconductor chip 200c. The third chip pads 210c included in the third semiconductor chip 200c may be exposed from the fourth semiconductor chip 200d, and may not be covered by the fourth semiconductor chip 200d.

In one or more example embodiments, the fourth semiconductor chip 200d may be stacked to be offset in the first direction with respect to the third semiconductor chip 200c. According to one or more example embodiments, the fourth chip pads 210d and the third chip pads 210c may be aligned in the first direction. Additionally, the fourth chip pads 210d may be adjacent to the first substrate pads 122 included in the package substrate 100.

As described above, the first, second, third and fourth semiconductor chips 200a, 200b, 200c, and 200d may be stacked so that chip pads may not be covered by an upper semiconductor chip. In one or more example embodiments, as shown in FIG. 21, the first, second, third and fourth semiconductor chips 200a, 200b, 200c, and 200d may be stacked in a cascade manner. For example, the first sides of three or more among the stacked semiconductor chips 200a, 200b, 200c, and 200d in the semiconductor package may be disposed at different positions.

The powder layer stacked structure 365a may include powder layers 370 and an upper molding layer 380 stacked in the vertical direction. The powder layer stacked structure 365a may cover the first, second, third and fourth semiconductor chips 200a, 200b, 200c, and 200d. Each of the powder layers 370 may include metal powder layers 330a, 330b, 340a, and 340b and a molding layer 350 arranged in the horizontal direction. The upper molding layer 380 may include only a molding layer.

Stacked metal powder layers 330a, 330b, 340a, and 340b included in the powder layer stacked structure 365a may serve as first and second bonding wire powder structures 360a, and 360b, and the molding layers 350 included in the stacked structure 365a may serve as a molding structure.

The first bonding wire powder structure 360a may be a stacked structure of sintered metal powders, and may be a single wiring structure. The second bonding wire powder structure 360b may be a stacked structure of sintered metal powders, and may be a single wiring structure.

The first bonding wire powder structure 360a may electrically connect the first substrate pad 122 and at least one of the first chip pad 210a and the second chip pad 210b. The second bonding wire powder structure 360b may electrically connect the first substrate pad 122 and at least one of the third chip pad 210c and the fourth chip pad 210d.

In one or more example embodiments, the first bonding wire powder structure 360a may connect the first substrate pad 122 and the first chip pad 210a to each other, and may connect the first chip pad 210a and the second chip pad 210b to each other. In one or more example embodiments, the second bonding wire powder structure 360b may connect the first substrate pad 122 and the third chip pad 210c to each other, and may connect the third chip pad 210c and the fourth chip pad 210d to each other.

A plurality of first bonding wire powder structures 360a and a plurality of second bonding wire powder structures 360b may be disposed on the package substrate 100.

The metal powder layer included in the first bonding wire powder structure 360a may include first bonding layers 330a and first metal layers 340a. The metal powder layer included in the second bonding wire powder structure 360b may include second bonding layers 330b and second metal layers 340b.

The first bonding layers 330a may contact the first and second chip pads 210a and 210b, and the second bonding layers 330b may contact the third and fourth chip pads 210c and 210d.

A bonding ball may not be between the first bonding wire powder structure 360a and the first chip pad 210a and between the first bonding wire powder structure 360a and the second chip pad 210b. The bonding ball may not be between the second bonding wire powder structure 360b and the third chip pad 210c and between the second bonding wire powder structure 360b and the fourth chip pad 210d. Therefore, when the first, second, third and fourth chip pads 210a, 210b, 210c, and 210d are formed, a size of the bonding ball may not need to be considered. Therefore, sizes of the first, second, third and fourth chip pads 210a, 210b, 210c, and 210d may be decreased, compared to the case where the bonding ball may be included.

Positions and shapes of the first and second bonding wire powder structures 360a and 360b may change depending on a stacked position of the metal powders.

The first bonding wire powder structure 360a may include first portions contacting upper surfaces of the first substrate pad 122 and the first and second chip pads 210a and 210b, and a second portion being connected between the first portions.

In one or more example embodiments, the second portions may include a portion extending in the vertical direction or a portion having an inclination. In one or more example embodiments, a portion of the second portion may be flat to face the upper surface of the package substrate 100.

The second bonding wire powder structure 360b may have third portions contacting the upper surfaces of the first substrate pad 122, the third and fourth chip pads 210c and 210d, and a fourth portion being connected between the third portions.

In one or more example embodiments, the fourth portions may include a portion extending in the vertical direction or a portion having an inclination. In one or more example embodiments, a portion of the fourth portion may be flat to face the upper surface of the package substrate 100.

In one or more example embodiments, in the cross-sectional view, the first and second bonding wire powder structures 360a and 360b may have the same width depending on their positions.

In one or more example embodiments, in the cross-sectional view, the first portion of the first bonding wire powder structure 360a may have a width equal to or smaller than a width of the second portion of the first bonding wire powder structure 360a. In one or more example embodiments, in the cross-sectional view, the third portion of the second bonding wire powder structure 360b may have a width equal to or smaller than a width of the fourth portion of the second bonding wire powder structure 360b.

The metal powder materials included in the first and second bonding wire powder structures 360a and 360b may be the same or different depending on their positions.

In one or more example embodiments, the first and second bonding wire powder structures 360a and 360b may have different metal materials depending on their positions. For example, the first portion of the first bonding wire powder structure 360a and the third portion of the second bonding wire powder structure 360b may include a first metal material having excellent bonding properties. Additionally, the second and fourth portions of the first and second bonding wire powder structures 360a and 360b may include a second metal material having a resistance lower than a resistance of the first metal material. For example, the first metal material may include lead (Pb), and the second metal material may include gold (Au) or silver (Ag).

In one or more example embodiments, the first and second bonding wire powder structures 360a and 360b may have the same metal depending on their positions.

The molding structure may be stacked molding layers 350, and the molding structure may cover the first and second bonding wire powder structures 360a and 360b and first, second, third and fourth semiconductor chips 200a, 200b, 200c and 200d.

The molding structure may be a stacked structure of sintered thermosetting resin powder. The first and second bonding wire powder structures 360a and 360b may be disposed in the molding structure.

The metal powder layers 330a, 330b, 340a, and 340b included in the first and second bonding wire powder structures 360a, and 360b and the molding layer 350 included in the molding structure may be disposed at the same horizontal level. The first and second bonding wire powder structures 360a and 360b may contact the molding structure. Positions of the first and second bonding wire powder structures 360a and 360b may be fixed by the molding structure.

The external connection member 400 may supply an electrical signal on the lower surface of the package substrate 100.

As described above with reference to one or more example embodiments, the semiconductor package may include the first bonding wire powder structure 360a that electrically connected between the package substrate 100 and each of the first and second semiconductor chips 200a and 200b, and the second bonding wire powder structure 360b that electrically connected between the third and fourth semiconductor chips 200c and 200d. The first and second bonding wire powder structure 360a and 130b may be sintered metal powders stacked. As the bonding balls are not provided at ends of the first and second bonding wire powder structures 360a and 360b, the sizes of the first, second, third and fourth chip pads 210a, 210b, 210c, and 210d may be decreased. Accordingly, the sizes of the first, second, third and fourth semiconductor chips 200a, 200b, 200c, and 200d may be decreased.

The first bonding wire powder structure 360a may be disposed to connect between the package substrate 100 and the first and second semiconductor chips 200a and 200b with a short distance. Additionally, the second bonding wire powder structure 360b may be disposed to connect between the package substrate 100 and the third and fourth semiconductor chips 200c and 200d with a short distance. Accordingly, an area and a height of the semiconductor package may be decreased.

Additionally, even though the first and second bonding wire powder structures 360a and 360b may have a narrow width, the first bonding wire powder structures 360a and the second bonding wire powder structures 360b may not move (e.g., sweep) toward one side of the semiconductor package. Therefore. a short defect due to the moving of the first bonding wire powder structures 360a and the second bonding wire powder structures 360b may not occur. Accordingly, the widths of the first and second bonding wire powder structures 360a and 360b may be decreased.

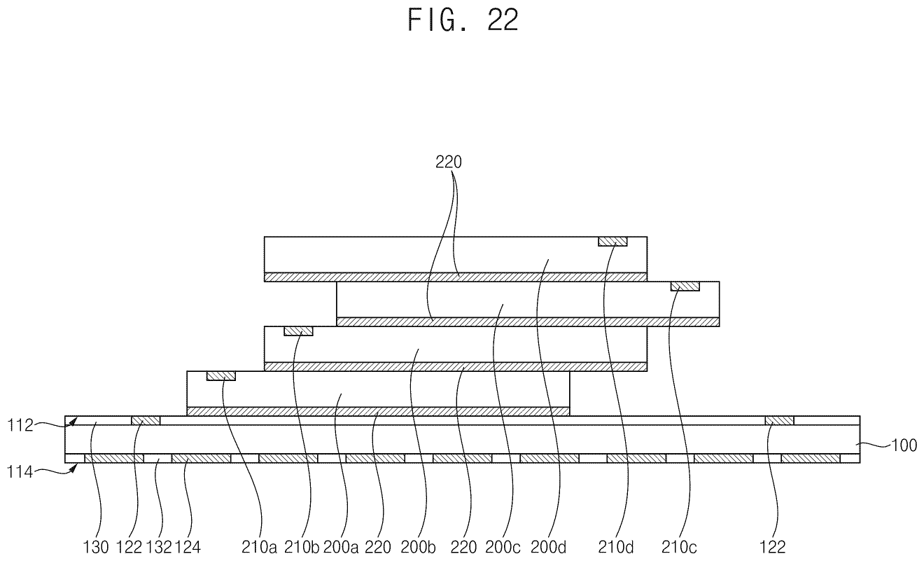

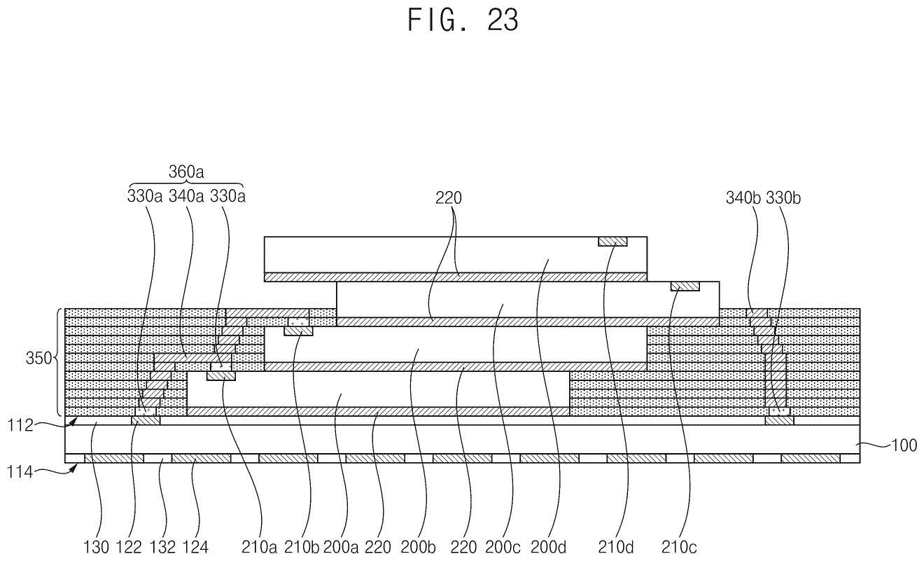

FIGS. 22 and 23 are cross-sectional views illustrating a method for manufacturing a semiconductor package according to one or more example embodiments.

Referring to one or more example embodiments shown in FIG. 22, first, second, third and fourth semiconductor chips 200a, 200b, 200c, and 200d may be stacked on the package substrate 100.

The adhesive layer 220 may be formed on a bottom of the first semiconductor chip 200a, and the bottom of the first semiconductor chip 200a and the first surface of the package substrate 100 may be bonded to each other by the adhesive layer 220.

The adhesive layer 220 may be formed on a bottom of the second semiconductor chip 200b. The bottom of the second semiconductor chip 200b and an upper surface of the first semiconductor chip 200a may be bonded to each other by the adhesive layer 220. According to one or more example embodiments, the second semiconductor chip 200b may not be aligned vertically on the first semiconductor chip 200a so that the first chip pad 210a of the first semiconductor chip 200a may not covered by the second semiconductor chip 200b.

The adhesive layer 220 may be formed on a bottom of the third semiconductor chip 200c, and the bottom of the third semiconductor chip 200c and an upper surface of the second semiconductor chip 200b may be bonded to each other by the adhesive layer 220. According to one or more example embodiments, the third semiconductor chip 200c may not be aligned vertically on the second semiconductor chip 200b so that the second chip pad 210b of the second semiconductor chip 200b may not be covered by the third semiconductor chip 200c.

The adhesive layer 220 may be formed on a bottom of the fourth semiconductor chip 200d, and the bottom of the fourth semiconductor chip 200d and an upper surface of the third semiconductor chip 200c may be bonded to each other by the adhesive layer 220. According to one or more example embodiments, the fourth semiconductor chip 200d may not be aligned vertically on third semiconductor chip 200c so that the third chip pad 210c of the third semiconductor chip 200c may not be covered by the fourth semiconductor chip 200d.

The first, second, third and fourth semiconductor chips 200a, 200b, 200c, and 200d may be disposed so that chip pads thereof may not be covered by an upper semiconductor chip. In one or more example embodiments, as shown in FIG. 22, the first, second, third and fourth semiconductor chips 200a, 200b, 200c, and 200d may be stacked in the cascade manner.

As described above with reference to one or more example embodiments, before forming bonding wires on each of the chip pads 210a, 210b, 210c, and 210d, a plurality of semiconductor chips 200a, 200b, 200c, and 200d included in the semiconductor package may be stacked on the package substrate 100.

Referring to one or more example embodiments shown in FIG. 23, the first metal powders may be sprayed on the package substrate 100 to form first and second bonded powder structures on the first substrate pad 122. A molding powder structure may be formed by spraying molding powders on the package substrate 100 on sides of the first and second bonding powder structures. Thereafter, the molding powder structure and the first and second bonding powder structures may be sintered to form a first powder layer including the molding layer 350 and the first and second bonding layers 330a and 330b.

The second metal powders may be sprayed on the first powder layer to form first and second metal powder structures on the first and second bonding layers 330a and 330b. A molding powder structure may be formed by spraying molding powders on the first powder layer on sides of the first and second metal powder structures. Thereafter, the molding powder structure and the first and second metal powder structures may be sintered to form a second powder layer including the molding layer 350 and the first and second metal layers 340a and 340b.

Thereafter, spraying of the metal powders, spraying of the molding powders, and the sintering process may be repeatedly performed on the second powder layer to form powder layers. Each of the powder layers may include at least one of the first and second metal layers 340a and 340b, and the first and second bonding layers 330a and 330b, and the molding layer 350.

In the process for forming the powder layer, when an uppermost powder layer is located between the second semiconductor chip 200b and the third semiconductor chip 200c, a first bonding wire powder structure 360a may be formed in the molding layer 350. The first bonding wire powder structure 360a may electrically connect the first substrate pad 122 and at least one of the first chip pad 210a and the second chip pad 210b. Additionally, a lower portion of the second bonding wire powder structure may be formed in the molding layer 350.

Referring to one or more example embodiments shown in FIG. 21 again, spraying of the metal powders, spraying of the molding powders, and the sintering process may be repeatedly performed on the powder layer to form powder layers. Each of the powder layers may include at least one of the first and second metal layers 340a and 340b and the first and second bonding layers 330a and 330b, and the molding layer 350.

In the process for forming the powder layer, an upper portion of the second bonding wire powder structure 360b may be formed. Accordingly, the second bonding wire powder structure 360b may be formed in the molding layer 350. The second bonding wire powder structure 360b may electrically connect the first substrate pad 122 and at least one of the third chip pad 210c and the fourth chip pad 210d.

Additionally, an uppermost molding layer may be formed to cover the fourth semiconductor chip 200d and the second bonding wire powder structure 360b.

The semiconductor package shown in FIG. 21 may be formed by the above processes.

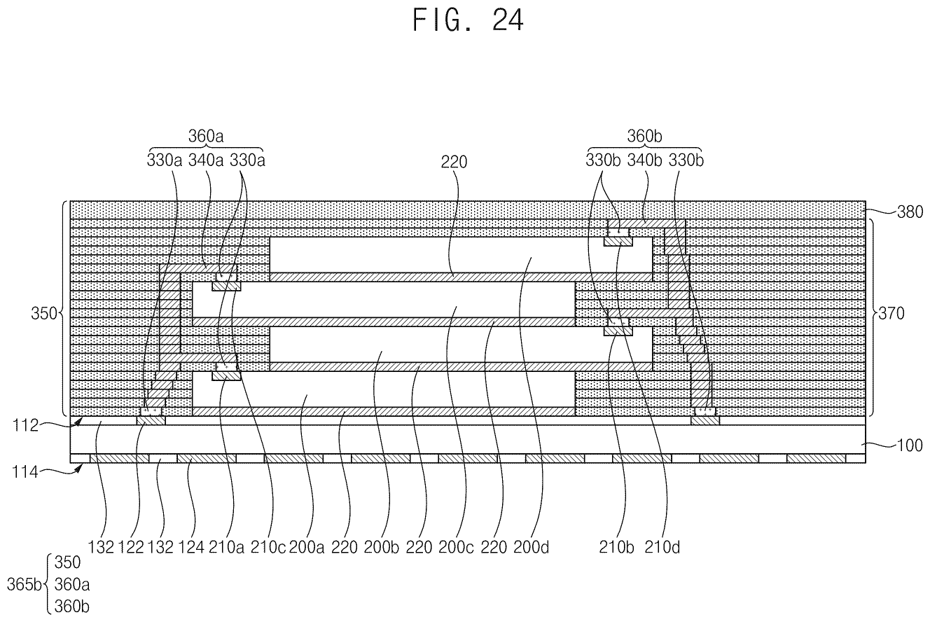

FIG. 24 is a cross-sectional view illustrating a semiconductor package according to one or more example embodiments.

The semiconductor package shown in FIG. 24 may be the same or similar to the semiconductor package shown in FIG. 21, except for a stacked structure of the semiconductor chip and a shape of the bonding wire powder structure.

Referring to one or more example embodiments shown in FIG. 24, the semiconductor package may include the package substrate 100, the plurality of semiconductor chips 200a, 200b, 200c, and 200d disposed on the package substrate 100, and a powder layer stacked structure 365b. The powder layer stacked structure 365b may include the molding structure, the first bonding wire powder structure 360a, and the second bonding wire powder structure 360b. The semiconductor package may further include the adhesive layers 220 and the external connection member 400.

The first, second, third and fourth semiconductor chips 200a, 200b, 200c, and 200d may be sequentially stacked on the package substrate 100. The first, second, third and fourth semiconductor chips 200a, 200b, 200c, and 200d may have a square shape, in a plan view. Each of the first, second, third and fourth semiconductor chips 200a, 200b, 200c, and 200d may have a first side and a second side facing the first side.

The first semiconductor chip 200a may include the first chip pads 210a on the first surface of the first semiconductor substrate. The first chip pads 210a may be disposed at an edge adjacent to the first side of the first semiconductor chip 200a.

The second, third and fourth semiconductor chips 200b, 200c, and 200d may have a structure substantially the same as or similar to a structure of the first semiconductor chip 200a. Second, third and fourth chip pads 210b, 210c, and 210d may be disposed on the second, third and fourth semiconductor chips 200b, 200c, and 200d, respectively.

The second semiconductor chip 200b may include the second chip pads 210b on the first surface of the second semiconductor substrate. In one or more example embodiments, the second chip pad 210b may be disposed at an edge adjacent to the second side of the second semiconductor chip 200b.

The third semiconductor chip 200c may include the third chip pads 210c on the first surface of the third semiconductor substrate. In one or more example embodiments, the third chip pad 210c may be disposed at an edge adjacent to the first side of the third semiconductor chip 200c.

The fourth semiconductor chip 200d may include the fourth chip pads 210d on the first surface of the fourth semiconductor substrate. In one or more example embodiments, the fourth chip pad 210d may be disposed at an edge adjacent to the second side of the fourth semiconductor chip 200d.

The first, second, third and fourth semiconductor chips 200a, 200b, 200c, and 200d may be stacked so that chip pads may not be covered by an upper semiconductor chip. In one or more example embodiments, as shown in FIG. 24, the first, second, third and fourth semiconductor chips 200a, 200b, 200c, and 200d may be stacked in a zigzag manner. That is, sidewalls of adjacent semiconductor chips in the vertical direction may be disposed at different positions. For example, the sidewalls of first and third semiconductor chips 200a and 200c may be disposed at the same position, and the sidewalls of the second and fourth semiconductor chips 200b may be disposed at the same position.

The powder layer stacked structure 365b may include powder layers 370 stacked in the vertical direction and an upper molding layer 380 disposed on an uppermost powder layer. Each of the powder layers 370 may include the metal powder layers 330a, 330b, 340a, and 340b and the molding layer 350 arranged in the horizontal direction. The upper molding layer 380 may include only the molding layer.

The stacked metal powder layers 330a, 330b, 340a, and 340b included in the powder layer stacked structure 365b may serve as one of first and second bonding wire powder structures 360a and 360b.

The first bonding wire powder structure 360a may connect the first substrate pad 122 included in the package substrate 100 and at least one of the first chip pad 210a and the third chip pad 210c. The second bonding wire powder structure 360b may connect the first substrate pad 122 included in the package substrate 100 and at least one of the second chip pad 210b and the fourth chip pad 210d.

The positions and shapes of the wire of the first and second bonding wire powder structures 360a and 360b may change depending on the positions of the metal powders.

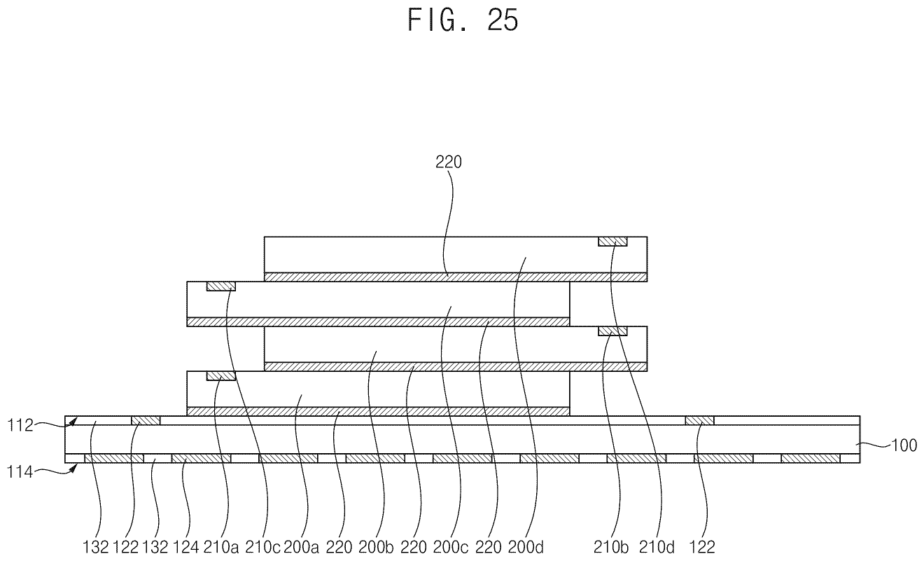

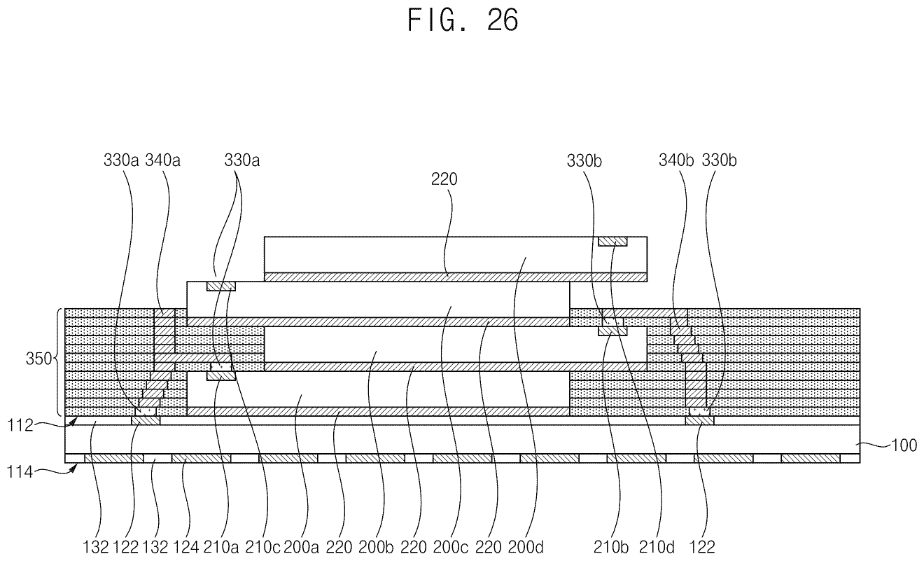

FIGS. 25 and 26 are cross-sectional views illustrating a method of manufacturing a semiconductor package according to one or more example embodiments.

Referring to one or more example embodiments shown in FIG. 25, the first, second, third and fourth semiconductor chips 200a, 200b, 200c, and 200d may be stacked on the package substrate 100.

The first, second, third and fourth semiconductor chips 200a, 200b, 200c, and 200d may be disposed so that the chip pads may not be covered by the upper semiconductor chip. In one or more example embodiments, the first, second, third and fourth semiconductor chips 200a, 200b, 200c, and 200d may be stacked in the zigzag manner.

As described according to one or more example embodiments, before forming the bonding wires on each of the chip pads, the plurality of semiconductor chips 200a, 200b, 200c, and 200d may be stacked on the package substrate 100.

Referring to one or more example embodiments shown in FIG. 26, the first metal powders may be sprayed on the package substrate 100 to form the first and second bonded powder structures on the first substrate pad 122. The molding powder structure may be formed on the package substrate 100 from sides of the first and second bonding powder structures by spraying the molding powders. Thereafter, the molding powder structure and the first and second bonding powder structures may be sintered to form a first powder layer including the molding layer 350 and the first and second bonding layers 330a and 330b.

Second metal powders may be sprayed on the first powder layer to form first and second metal powder structures on the first and second bonding layers 330a and 330b. A molding powder structure may be formed on the first powder layer from the side of the first and second metal powder structures by spraying the molding powders. Thereafter, the molding powder structure and the first and second metal powder structures may be sintered to form a second powder layer including the molding layer 350 and the first and second metal layers 340a and 340b.

Thereafter, spraying of the metal powders, spraying of the molding powders, and the sintering process may be repeatedly performed on the second powder layer to form powder layers. The powder layer may include and a molding layer 350 and at least one of the first and second metal layers 340a and 340b and the first and second bonding layers 330a and 330b.

In the FIG. 26, a lower portion of the first bonding wire powder structure and a lower portion of the second molding wire powder structure formed in the molding layer 350 may be shown.

Referring to one or more example embodiments shown in FIG. 24 again, spraying of the metal powders, spraying of the molding powders, and the sintering process may be repeatedly performed on the powder layer to form powder layers 370. The powder layer 370 may include a molding layer 350 and at least one of the first and second metal layers 340a and 340b, the first and second bonding layers 330a and 330b.

By forming the powder layers 370, upper portions of the first and second bonding wire powder structures 360a and 360b may be formed. Accordingly, the first and second bonding wire powder structures 360a and 360b may be formed in the molding layer 350. The first bonding wire powder structure 360a may electrically connect the first substrate pad 122 and at least one of the first chip pad 210a and the third chip pad 210c. The second bonding wire powder structure 360b may electrically connect the first substrate pad 122 and at least one of the second chip pad 210b and the fourth chip pad 210d.

Additionally, an upper molding layer 380 may be formed to cover the fourth semiconductor chip 200d and the second bonding wire powder structure 360b.

The semiconductor package shown in FIG. 25 may be manufactured by above processes.

The foregoing is illustrative of one or more example embodiments of and is not to be construed as limiting thereof. Although one or more example embodiments have been described, those skilled in the art will readily appreciate that many modifications are possible in the one or more example embodiments without materially departing from the spirit and scope of the following claims.

What is claimed is:

1. A semiconductor package, comprising:
a package substrate comprising a substrate pad;
at least one semiconductor chip comprising a chip pad,
wherein the at least one semiconductor chip being provided on the package substrate; and
a powder layer stacked structure covering the semiconductor chip,
wherein the powder layer stacked structure is provided on the package substrate,
wherein the powder layer stacked structure comprises powder layers stacked in a vertical direction,
wherein each of the powder layers comprises a metal powder layer and a molding layer arranged in a horizontal direction,
wherein the metal powder layers of the powder layer stacked structure are connected to each other to form a bonding powder structure, and
wherein the bonding powder structure electrically connects the substrate pad and the chip pad.

2. The semiconductor package of claim 1, wherein the metal powder layer in each of the powder layers is an aggregate of sintered metal powders, and
wherein the molding layer is an aggregate of sintered mold powders.

3. The semiconductor package of claim 2, wherein the mold powders comprises thermosetting resin powder.

4. The semiconductor package of claim 1, wherein the molding layer of each of the powder layers contacts sidewalls of the metal powder layer, and supports the sidewalls of the metal powder layer.

5. The semiconductor package of claim 1, wherein the metal powder layers of the bonding wire powder structure comprise at least one of gold (Au), silver (Ag), copper (Cu), aluminum (Al), tungsten (W), nickel (Ni), and molybdenum (Mo), chromium (Cr), tin (Sn), titanium (Ti), or lead (Pb).

6. The semiconductor package of claim 1, wherein the metal powder layers of the bonding wire powder structure comprise:
a first bonding layer directly contacting the substrate pad and the chip pad; and
a first metal layer contacting the first bonding layer.

7. The semiconductor package of claim 6, wherein the first bonding layer and the first metal layer comprise a same material.

8. The semiconductor package of claim 6, wherein a material of the first metal layers has a resistance lower than a resistance of a material of the first bonding layers.

9. The semiconductor package of claim 8, wherein the first bonding layer comprises lead (Pb), and the first metal layer comprises gold (Au) or silver (Ag).

10. The semiconductor package of claim 6, wherein the first bonding layer has a width, which is equal to or smaller than a width of the first metal layer, in a cross-sectional view.

11. The semiconductor package of claim 6, wherein the first bonding layer covers from 60% to 95% of an upper surface of the chip pad.

12. The semiconductor package of claim 1, wherein the bonding wire powder structure comprises: a first portion contacting the substrate pad, a second portion contacting the chip pad, and a third portion connecting between the first portion and the second portion, and
wherein in at least a portion of the third portion disposed higher than an upper surface of the chip pad is flat and faces an upper surface of the package substrate.

13. The semiconductor package of claim 1, wherein the bonding wire powder structure comprises: a first portion contacting the substrate pad, a second portion contacting the chip pad, and a third portion connecting between the first portion and the second portion, and
wherein in at least a portion of the third portion has inclination with respect to an upper surface of the package substrate.

14. The semiconductor package of claim 1, wherein the bonding wire powder structure comprises: a first portion contacting the substrate pad, a second portion contacting the chip pad, and a third portion connecting between the first portion and the second portion, and
wherein in at least a portion of the third portion has a vertical inclination with respect to an upper surface of the package substrate.

15. A semiconductor package, comprising:
a package substrate comprising a substrate pad;
a first semiconductor chip comprising a first chip pad,
wherein the first semiconductor chip is provided on the package substrate;
a second semiconductor chip comprising a second chip pad,
wherein the second semiconductor chip is provided on the first semiconductor chip, and
wherein the second semiconductor chip exposes the first chip pads; and
a powder layer stacked structure covering the first semiconductor chip and the second semiconductor chip,
wherein the powder layer stacked structure is provided on the package substrate,
wherein the powder layer stacked structure comprises powder layers stacked in a vertical direction,
wherein each of the powder layers comprises a metal powder layer and a molding layer arranged in a horizontal direction,
wherein the metal powder layers of the powder layer stacked structure are connected to each other to form a bonding powder structure, and
wherein the bonding powder structure electrically connects the substrate pad and at least one of the first chip pad and the second chip pad.

16. The semiconductor package of claim 15, wherein a plurality of semiconductor chips are further stacked on the second semiconductor chip, and
wherein adjacent semiconductor chips in the vertical direction are not vertically aligned with respect to each other so that the chip pads of the semiconductor chips are exposed.

17. The semiconductor package of claim 15, wherein the metal powder layer in each of the powder layers is an aggregate of sintered metal powders, and
wherein the molding layer is an aggregate of sintered mold powders.

18. The semiconductor package of claim 15, wherein the metal powder layers of the bonding wire powder structure comprise:
a first bonding layer directly contacting the substrate pad and the first chip pads and the second chip pads; and
a first metal layer contacting the first bonding layer, and
wherein the first bonding layer has a width, which is equal to or smaller than a width of the first metal layer, in a cross-sectional view.

19. A method for manufacturing a semiconductor package, the method comprising:
stacking, on a package substrate, at least one semiconductor chip comprising a chip pad,
wherein the package substrate comprises a substrate pad;
forming a first powder layer on the package substrate, the first powder layer comprising:
a metal powder layer contacting the substrate pad; and
a molding layer on the package substrate, the molding layer extending from sides of the metal powder layer; and
repeatedly forming a plurality of powder layers, each comprising the metal powder layer and the molding layer, on the first powder layer to form a bonding wire powder structure comprising the metal powder layers and a molding structure comprising the molding layers,
wherein the bonding wire powder structure is formed on the package substrate and the semiconductor chip, and
wherein the bonding wire powder structure electrically connects the substrate pad and the chip pad.

20. The method of claim 19, wherein the forming the first powder layer comprises:
selectively spraying metal powders on an upper surface of the substrate pad to form a bonding powder structure;
spraying molding powders on the package substrate from a side of the bonding powder structure to form a molding powder structure; and
sintering the molding powder structure and the bonding powder structure to form the metal powder layer and the molding layer.
